(19) United States
(12) Patent Application Publication
(10) Pub. No.: US 2015/0252125 A1
(43) Pub. Date: Sep. 10, 2015

(54) CURABLE RESIN COMPOSITIONS AND BARRIER STACKS INCLUDING THE SAME

(71) Applicant: CHEIL INDUSTRIES INC., Uiwang-si (KR)

(72) Inventors: Lorenza Moro, Palo Alto, CA (US); Damien Boesch, San Jose, CA (US); Sina Maghsoodi, San Jose, CA (US)

(21) Appl. No.: 14/256,873

(22) Filed: Apr. 18, 2014

Related U.S. Application Data
(60) Provisional application No. 61/950,787, filed on Mar. 10, 2014.

(51) Int. Cl. C08F 130/08; B05D 3/06; B05D 3/02; C09D 143/04

(52) U.S. Cl. CPC C08F 130/08; C09D 143/04; B05D 3/067; B05D 3/068; B05D 3/0254

(57) ABSTRACT

A barrier stack includes a decoupling layer comprising a siloxane containing resin composition, and a barrier layer on the decoupling layer. The siloxane containing resin composition comprises a moiety derived from a siloxane monomer represented by Formula 1. A method of forming the decoupling layer includes depositing a curable resin composition comprising a siloxane monomer on the substrate, and curing the curable resin composition. The siloxane monomer of the curable resin composition includes a monomer represented by Formula 1.

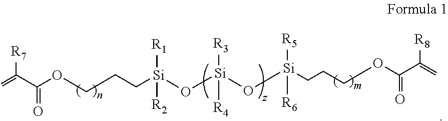

### CROSS-REFERENCE TO RELATED APPLICATION(S)

This application claims priority to and the benefit of U.S. Provisional Application Ser. No. 61/950,787, filed on Mar. 10, 2014, the entire content of which is incorporated herein by reference.

### BACKGROUND

Many devices, such as organic light emitting devices and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are often encapsulated by incorporating a barrier stack adjacent one or both sides of the device.

In general, a barrier stack includes at least one barrier layer and at least one decoupling or smoothing layer, and can be deposited directly on the device to be protected, or may be deposited on a separate film or support, and then laminated onto the device. The decoupling layer(s) serve to provide a smooth and generally planar surface on which to deposit the barrier layer(s). The barrier layer(s) can be deposited by any of various techniques (e.g., vacuum deposition processes or atmospheric processes), but the deposition of suitably dense layers with appropriate barrier properties is typically achieved by supplying energy to the material that will ultimately form the layer. The energy supplied to the material can be thermal energy, but in many deposition processes, ionization radiation is used to increase the ion production in the plasma and/or to increase the number of ions in the evaporated material streams. The produced ions are then accelerated toward the substrate either by applying a DC or AC bias to the substrate, or by building up a potential difference between the plasma and the substrate.

The higher energy supplied by these plasma-based deposition techniques provides certain benefits. For example, higher energy deposition techniques provide higher deposition rates, which in turn increase the throughput of the deposition process. Additionally, these higher energy processes lead to the formation of denser, amorphous inorganic layers which have good barrier performance. Moreover, the higher energy deposition process creates a good interface and good adhesion between layers of the barrier stack.

However, the plasma used to deposit the barrier layers can damage the underlying decoupling layers. For example, the plasma-based techniques can cause bond breakage in the polymer structure of the decoupling layers, resulting in the creation of small volatile molecules.

The damage to the underlying decoupling layers can also lead to damage of the devices the barrier stacks are intended to protect. In particular, certain devices, such as organic light emitting devices, are sensitive to plasma, and can be damaged when a plasma based or plasma assisted deposition process is used to deposit the layers of the barrier stack. Damage caused by the plasma based or plasma assisted deposition of the layers of the barrier stack have a negative impact on the electrical and/or luminescent properties of the protected (or encapsulated) device. The type and extent of damage caused by the plasma based or plasma assisted deposition process may vary depending on the type of device, and even on the manufacturer of the device, with some devices registering significant damage and others registering little or no damage. However, some typical effects of plasma damage on organic light emitting devices include higher voltage requirements for achieving the same level of luminescence, reduced luminescence, and undesirable modifications to the properties of certain polymers.

### SUMMARY

According to embodiments of the present invention, a barrier stack includes a decoupling layer comprising a siloxane containing resin composition, and a barrier layer on the decoupling layer. The barrier stack may further include a tie layer, and the decoupling layer may be on the tie layer.

The siloxane containing resin composition may include a moiety derived from a siloxane monomer represented by Formula 1:

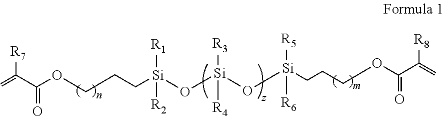

In Formula 1, n and m may each independently be 1 to 10, z may be 0 to 5, and R7 and R8 may each independently be hydrogen or a methyl group. Also, R1 through R6 may each independently be hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, a —O—SiR₉R₁₀R₁₁ group, or a combination thereof. In the —O—SiR₉R₁₀R₁₁ group, R9, R10 and R11 may each independently be hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof.

In some embodiments, for example, the siloxane monomer may include a monomer represented by Formula 2, a monomer represented by Formula 3, a monomer represented by Formula 4, a monomer represented by Formula 5 and/or a monomer represented by Formula 6.

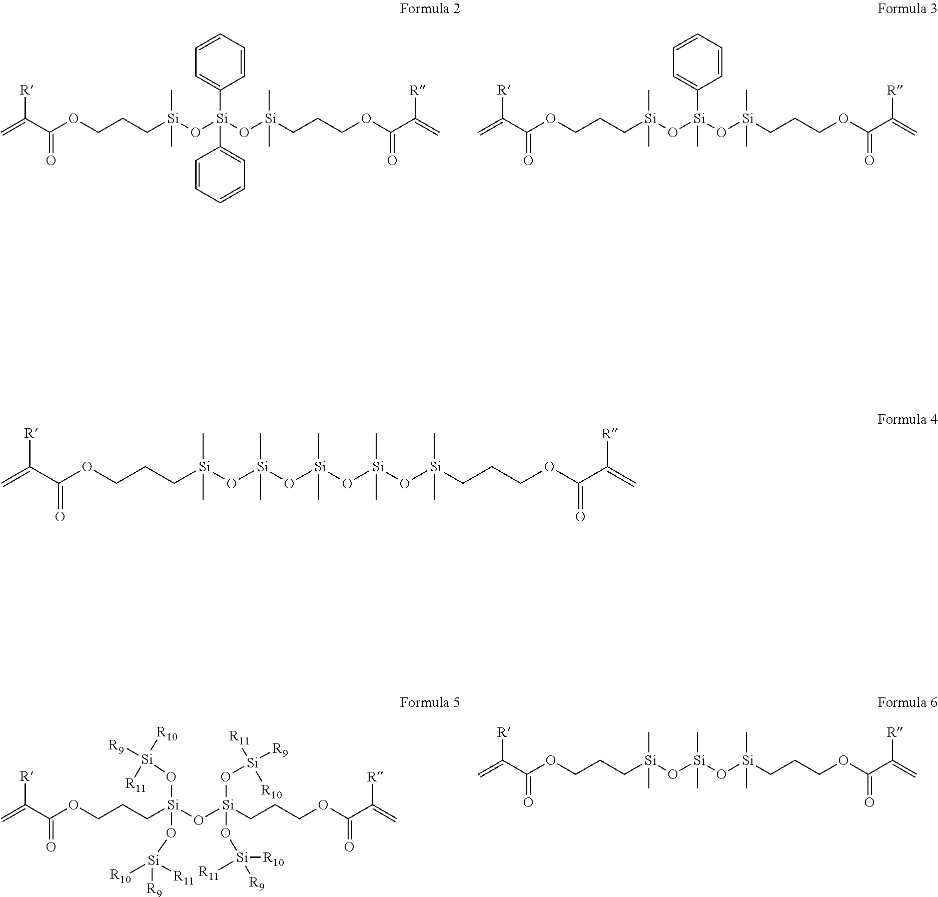

In Formulae 2, 3, 4, 5 and 6, R′ and R″ are each independently hydrogen or a methyl group. Also, R9, R10 and R11 may each independently be hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof. Additionally, the R9s, R10s and R11s within the same compound may be the same or different from one another. For example, in some embodiments, the siloxane monomer represented by Formula 1 comprises 1,5-bis(acryloxypropyl)-1,1,5,5-tetramethyl-3,3-diphenyl trisiloxane represented by Formula 2a, 1,5-bis(methacryloxypropyl)-1,1,5,5-tetramethyl-3,3-diphenyl trisiloxane represented by Formula 2b, 1,5-bis(acryloxypropyl)-1,1,3,5,5-pentamethyl-3-phenyl trisiloxane represented by Formula 3a, 1,5-bis(methacryloxypropyl)-1,1,3,5,5-pentamethyl-3-phenyl trisiloxane represented by Formula 3b, 1,9-bis(acryloxypropyl)-1,1,3,3,5,5,7,7,9,9-decamethyl hexasiloxane represented by Formula 4a, 1,9-bis(methacryloxypropyl)-1,1,3,3,5,5,7,7,9,9-decamethyl hexasiloxane represented by Formula 4b, 1,3-bis(3-acryloxypropyl)tetrakis(trimethylsiloxy)disiloxane as represented by Formula 5a, 1,3-bis(3-methacryloxypropyl)tetrakis(trimethylsiloxy)disiloxane as represented by Formula 5b, 1,5-bis(acryloxypropyl)-1,1,3,3,5,5-hexamethyl trisiloxane represented by Formula 6a, 1,5-bis(methacryloxypropyl)-1,1,3,3,5,5-dexamethyl trisiloxane represented by Formula 6b:

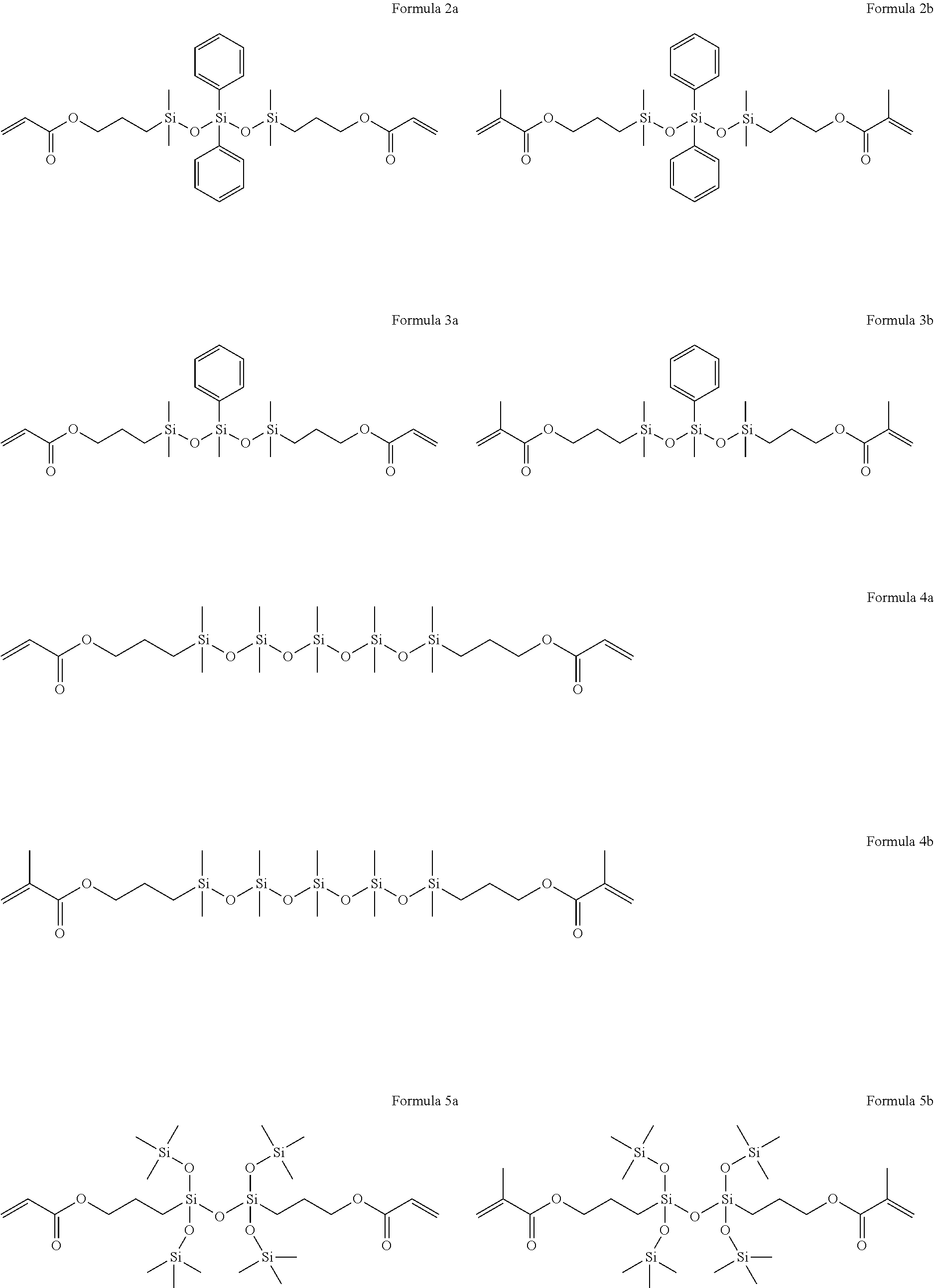

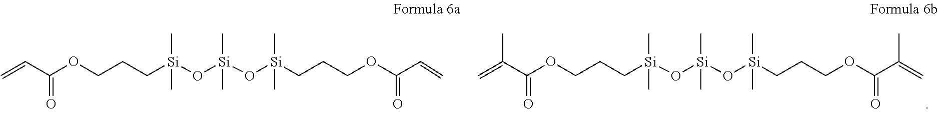

The siloxane containing resin composition may further include a moiety derived from an acrylate or methacrylate monomer. The acrylate or methacrylate monomer may include a monofunctional acrylate, a monofunctional methacrylate, a difunctional acrylate, a difunctional methacrylate, a trifunctional acrylate, and/or a trifunctional methacrylate. For example, in some embodiments, the acrylate or methacrylate monomer may include lauryl acrylate, dodecyl dimethacrylate, and/or trimethylolpropane triacrylate.

According to some embodiments of the present invention, a method of making a barrier stack includes forming a decoupling layer including a siloxane containing resin composition over a substrate, and forming a barrier layer over the decoupling layer. The method may further include forming a tie layer between the substrate and the decoupling layer.

Forming the decoupling layer over the substrate may include depositing a curable resin composition including a siloxane monomer on the substrate, and curing the curable resin composition. The curable resin composition may be deposited on the substrate by, for example, flash evaporation or inkjet printing. The curable resin composition may be cured by, for example, thermal curing, UV radiation, or electron beam treatment.

### BRIEF DESCRIPTION OF THE DRAWINGS

The patent or application file contains at least one drawing executed in color. Copies of this patent or patent application publication with color drawing(s) will be provided by the office upon request and payment of the necessary fee.

These and other features and advantages of the present invention will be better understood by reference to the following detailed description when considered in conjunction with the following drawings, in which:

FIG. 1 is a schematic view of a barrier stack according to an embodiment of the present invention;

FIG. 2 is a schematic view of a barrier stack according to another embodiment of the present invention; and

FIG. 3 is a schematic view of a barrier stack according to yet another embodiment of the present invention.

FIG. 4 is a photograph of a substrate (after UV exposure and rest time) prepared with the curable resin composition of Example 10;

FIG. 5 is a photograph of a substrate (after UV exposure and rest time) prepared with the curable resin composition of Example 11;

FIG. 6 is a photograph of a substrate (after UV exposure and rest time) prepared with the curable resin composition of Example 12;

FIG. 7 is a photograph of a substrate (after UV exposure and rest time) prepared with the curable resin composition of Example 13;

FIG. 8 is a photograph of a substrate (after UV exposure and rest time) prepared with the curable resin composition of Example 14;

FIG. 9 is a photograph of a substrate (after UV exposure and rest time) prepared with the curable resin composition of Comparative Example 1;

FIG. 10A is a graph showing the WVTR over time of the calcium coupons prepared with the curable resin composition of Example 5 on which the barrier layer was deposited by pulsed DC sputtering;

FIG. 10B is a graph showing the WVTR over time of the calcium coupons prepared with the curable resin composition of Example 5 on which the barrier layer was deposited by pulsed AC sputtering;

FIG. 11A is a photograph of the substrate including the calcium coupons prepared with the curable resin composition of Example 5 500 hours after barrier deposition by pulsed DC sputtering;

FIG. 11B is a photograph of the substrate including the calcium coupons prepared with the curable resin composition of Example 5 500 hours after barrier deposition by pulsed AC sputtering;

FIG. 12A is a photograph of a glass substrate after UV exposure prepared using the curable resin composition of Example 4, and an oxide layer deposited by DC sputtering;

FIG. 12B is a photograph of a glass substrate after UV exposure prepared using the curable resin composition of Example 4, and an oxide layer deposited by AC sputtering;

FIG. 13A is an optical profilometry image of a barrier stack prepared using the curable resin composition of Example 5 after deposition of the layers of the barrier stack at 10× magnification;

FIG. 13B is an optical profilometry image of the barrier stack of FIG. 13A at 50× magnification;

FIG. 14A is an optical profilometry image of a barrier stack prepared using the curable resin composition of Example 5 after exposure in an 85° C. dry oven for 139 hours at 10× magnification;

FIG. 14B is an optical profilometry image of the stack of FIG. 14A at 50× magnification;

FIG. 15A is an optical profilometry image of a barrier stack prepared using the curable resin composition of Example 5 after exposure in a 40° C. oven at 90% relative humidity for 139 hours at 10× magnification;

FIG. 15B is an optical profilometry image of the stack of FIG. 15A at 50× magnification;

FIG. 16A is an optical profilometry image of a barrier stack prepared using the curable resin composition of Example 5 after exposure in an 85° C. oven at 85% relative humidity for 139 hours at 10× magnification; and

FIG. 16B is an optical profilometry image of the barrier stack of FIG. 16A at 50× magnification.

### DETAILED DESCRIPTION

According to some embodiments of the present invention, a curable resin composition includes a monomer mixture that includes a siloxane monomer. In some embodiments, the monomer mixture includes the siloxane monomer in addition to other monomers that can be selected to improve cross-linking, wettability, or other properties. For example, in some embodiments, the monomer mixture includes a siloxane monomer represented by CH₂—CH—CO—O—CH₂CH₂—(CH₂)ₙ—(SiR¹R²)—O—(SiR³R⁴—O)_{z}—(SiR⁵R⁶)—(CH₂)ₘ—CH₂CH₂—O—CO—CH—CH₂ (depicted below as Formula 1).

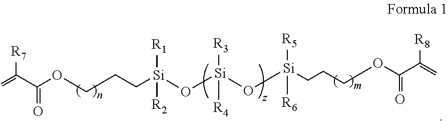

In Formula 1, R1 through R6 may each independently be hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, a —O—SiR₉R₁₀R₁₁ group, or a combination thereof. In the —O—SiR₉R₁₀R₁₁ group, R9, R10 and R11 may each independently be hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof.

In some embodiments, for example, R1 through R6 may each independently be hydrogen, a substituted or unsubstituted C1 to C10 alkyl group, a substituted or unsubstituted C3 to C20 cycloalkyl group, a substituted or unsubstituted C1 to C10 hydroxyalkyl group, a substituted or unsubstituted C6 to C20 aryl group, a substituted or unsubstituted C2 to C20 heteroaryl group, a substituted or unsubstituted C2 to C10 alkenyl group, a substituted or unsubstituted C1 to C10 alkoxy group, a substituted or unsubstituted lactone group, a substituted or unsubstituted carboxyl group, a substituted or unsubstituted glycidyl ether group, a hydroxyl group, a —O—SiR₉R₁₀R₁₁ group, or a combination thereof. Additionally, in the —O—SiR₉R₁₀R₁₁ group, R9, R10 and R11 may each independently be hydrogen, a substituted or unsubstituted C1 to C10 alkyl group, a substituted or unsubstituted C3 to C20 cycloalkyl group, a substituted or unsubstituted C1 to C10 hydroxyalkyl group, a substituted or unsubstituted C6 to C20 aryl group, a substituted or unsubstituted C2 to C20 heteroaryl group, a substituted or unsubstituted C2 to C10 alkenyl group, a substituted or unsubstituted C1 to C10 alkoxy group, a substituted or unsubstituted lactone group, a substituted or unsubstituted carboxyl group, a substituted or unsubstituted glycidyl ether group, a hydroxyl group, or a combination thereof.

In some embodiments, for example, R1 through R6 may each independently be hydrogen, a substituted or unsubstituted alkyl, a substituted or unsubstituted cycloalkyl, a substituted or unsubstituted aryl, or a combination thereof. For example, in some embodiments, R1 through R6 are each independently a lower alkyl (i.e., an alkyl having from 1 to 6 carbon atoms), a phenyl group, a —O—SiR₉R₁₀R₁₁ group, or a combination thereof. Also, in some embodiments, in the —O—SiR₉R₁₀R₁₁ group, R9 through R11 may each independently be hydrogen, a substituted or unsubstituted alkyl, a substituted or unsubstituted cycloalkyl, a substituted or unsubstituted aryl, or a combination thereof. For example, in some embodiments, R1 through R6 are each independently a lower alkyl (i.e., an alkyl having from 1 to 6 carbon atoms), a phenyl group, or a combination thereof.

In some exemplary embodiments, for example, R1 through R6 are each independently methyl, phenyl, a —O—SiR₉R₁₀R₁₁ group, or a combination thereof. Also, in some embodiments, in the —O—SiR₉R₁₀R₁₁ group, R9 through R11 may each independently be hydrogen or methyl.

Additionally, in Formula 1, R7 and R8 may each independently be hydrogen or a methyl group, n and m may each independently be 1 to 10, and z may be 0 to 5. For example, in some embodiments, n and m may each independently be 1 to 6, and z may be 0 to 3.

In some embodiments, the monomer mixture includes a monomer represented by Formula 2, a monomer represented by Formula 3, a monomer represented by Formula 4, a monomer represented by Formula 5 and/or a monomer represented by Formula 6.

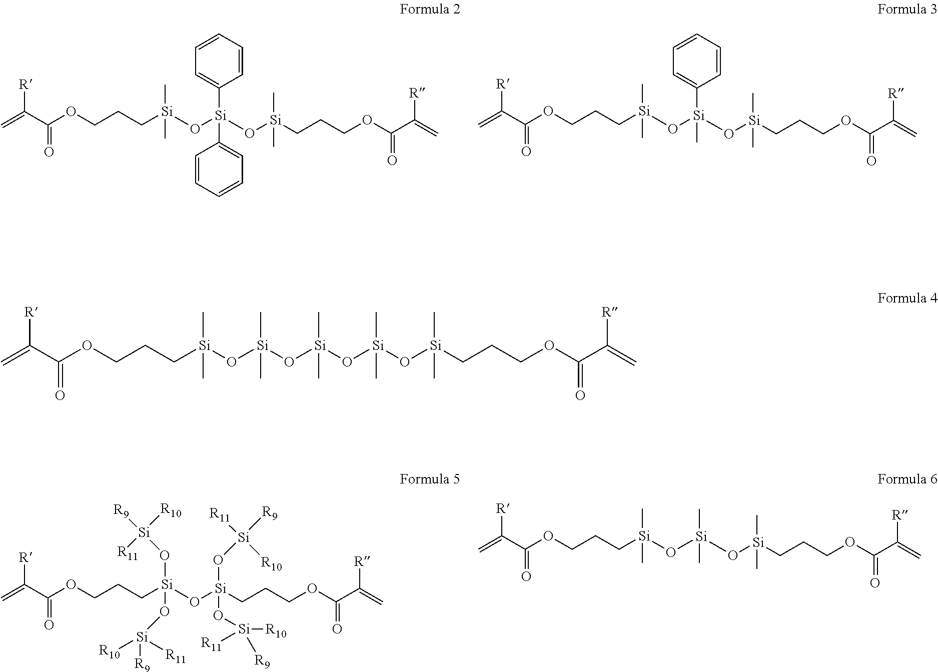

In Formulae 2 through 6, R′ and R″ are each independently hydrogen or a methyl group. Also, R9, R10 and R11 are as defined above with respect to the —O—SiR₉R₁₀R₁₁ group in Formula 1. Additionally, the R9s, R10s and R11s within the same compound may be the same or different from one another.

For example, in some embodiments, the siloxane monomer represented by Formula 1 comprises 1,5-bis(acryloxypropyl)-1,1,5,5-tetramethyl-3,3-diphenyl trisiloxane represented by Formula 2a, 1,5-bis(methacryloxypropyl)-1,1,5,5-tetramethyl-3,3-diphenyl trisiloxane represented by Formula 2b, 1,5-bis(acryloxypropyl)-1,1,3,5,5-pentamethyl-3-phenyl trisiloxane represented by Formula 3a, 1,5-bis(methacryloxypropyl)-1,1,3,5,5-pentamethyl-3-phenyl trisiloxane represented by Formula 3b, 1,9-bis(acryloxypropyl)-1,1,3,3,5,5,7,7,9,9-decamethyl hexasiloxane represented by Formula 4a, 1,9-bis(methacryloxypropyl)-1,1,3,3,5,5,7,7,9,9-decamethyl hexasiloxane represented by Formula 4b, 1,3-bis(3-acryloxypropyl)tetrakis(trimethylsiloxy)disiloxane as represented by Formula 5a, 1,3-bis(3-methacryloxypropyl)tetrakis(trimethylsiloxy)disiloxane as represented by Formula 5b, 1,5-bis(acryloxypropyl)-1,1,3,3,5,5-hexamethyl trisiloxane represented by Formula 6a, and/or 1,5-bis(methacryloxypropyl)-1,1,3,3,5,5-hexamethyl trisiloxane represented by Formula 6b:

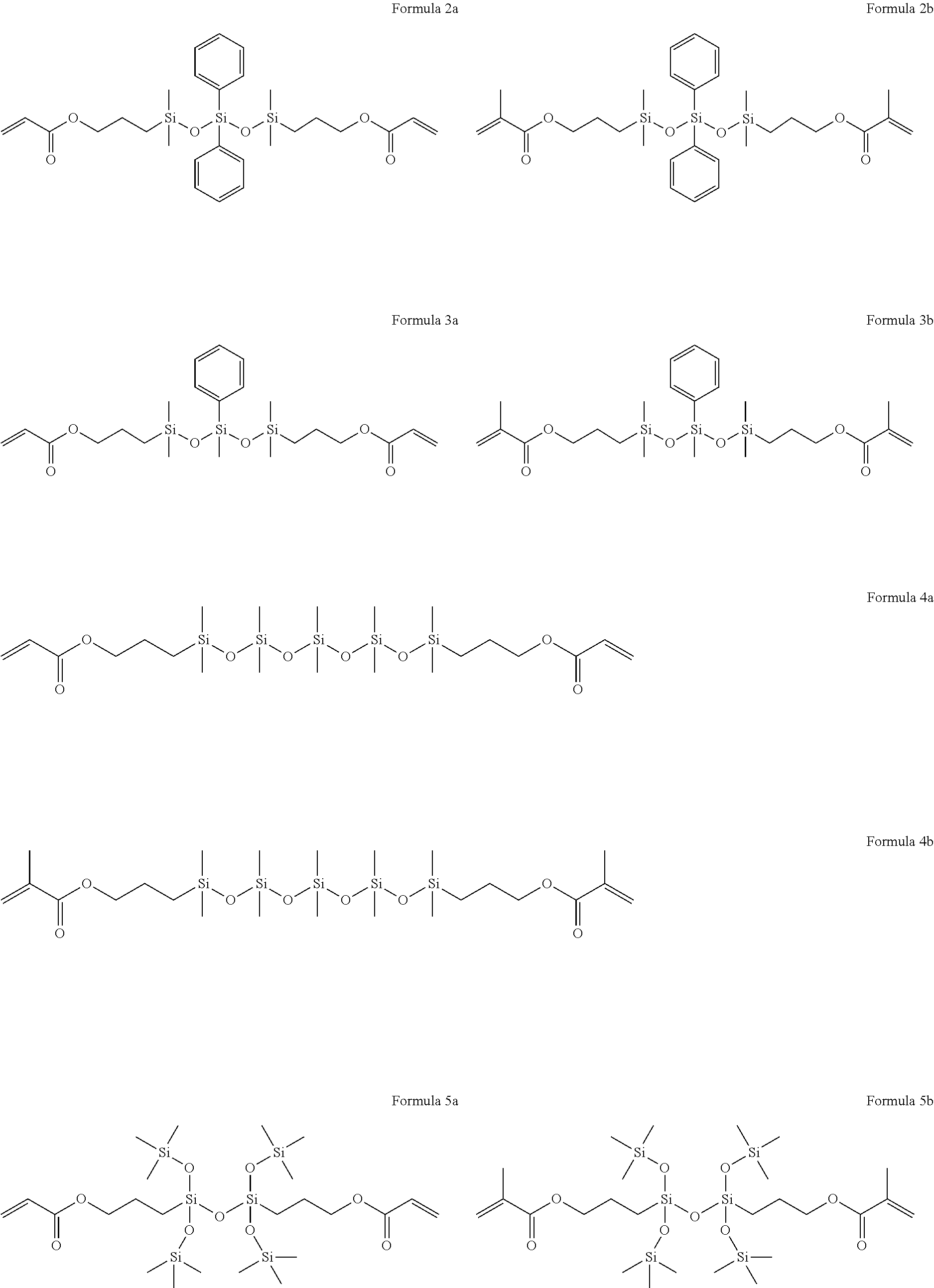

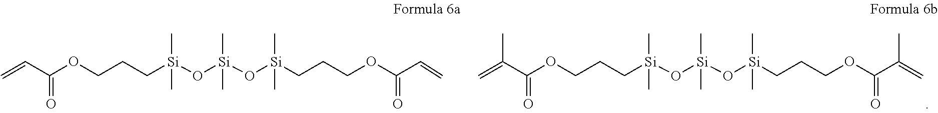

In some embodiments, the monomer mixture may include a combination of two or more different siloxane monomers, and in some embodiments, each of the two or more different siloxane monomers in the monomer mixture may be independently selected from monomers represented by Formulae 2 through 6. In some embodiments, for example, each of the two or more different siloxane monomers in the monomer mixture may be independently selected from monomers represented by Formulae 2a, 2b, 3a, 3b, 4a, 4b, 5a, 5b, 6a and 6b. When the monomer mixture includes a mixture of different siloxane monomers, the different siloxane monomers may be provided in any suitable mixing ratio, and those of ordinary skill in the art would be capable of selecting a suitable mixing ratio based on the intended application of the curable resin composition.

The siloxane monomer may be present in the monomer mixture in an amount of about 20 mol % to about 70 mol %. In some embodiments, for example, the siloxane monomer may be present in the monomer mixture in an amount of about 25 mol % to about 60 mol %. For example, in some embodiments, the siloxane monomer may be present in the monomer mixture in an amount of about 30 mol % to about 50 mol %. In some embodiments, the siloxane monomer is present in the monomer mixture in an amount of about 30 mol %, about 50 mol %, about 51 mol %, about 51.6 mol %, about 52 mol %, or about 70 mol %.

In some embodiments, the monomer mixture may further include additional monomers for adjusting cross-linking, wettability, or other properties of the curable resin composition. For example, in some embodiments, the monomer mixture may further include an acrylate-based monomer. As used herein, the term “acrylate” and similar terms includes both acrylates and methacrylates, as those terms are generally understood by those of ordinary skill in the art. In some embodiments, for example, the acrylate-based monomer may include a mono-acrylate monomer, a diacrylate monomer and/or a triacrylate monomer. For example, in some embodiments, the acrylate-based monomer may include a mono-acrylate monomer and a diacrylate monomer, and in other embodiments, the acrylate-based monomer may include a mono-acrylate monomer and a triacrylate monomer, a diacrylate monomer and a triacrylate monomer, or a mono-acrylate monomer, a diacrylate monomer and a triacrylate monomer. In some embodiments, for example, the acrylate monomer may include at least a triacrylate monomer in order to increase the degree of crosslinking in the cured polymer film. Any suitable acrylate-based monomers may be used, and those of ordinary skill in the art would be capable of selecting the particular acrylate-based monomer(s). Nonlimiting examples of suitable mono-acrylate monomers include lauryl acrylate, isobornyl acrylate, isobornyl methacrylate, and tripropylene glycol methylether acrylate. In some embodiments, for example, the monoacrylate may include lauryl acrylate. Nonlimiting examples of suitable diacrylate monomers include dodecyl dimethacrylate, 1,6-hexanediol diacrylate, tripropylene glycol diacrylate, propoxylated hexanediol diacrylate, and tricyclodecane dimethanol diacrylate. In some embodiments, for example, the diacrylate may include dodecyl dimethacrylate. Nonlimiting examples of suitable triacrylate monomers include trimethylol propane triacrylate, and ethoxylated trimethylolpropane triacrylate. In some embodiments, for example, the triacrylate may include trimethylol propane triacrylate.

The acrylate-based monomer may be present in the monomer mixture in an amount of about 30 mol % to about 80 mol %. In some embodiments, for example, the acrylate-based monomer may be present in the monomer mixture in an amount of about 35 mol % to about 75 mol %. For example, in some embodiments, the acrylate-based monomer may be present in the monomer mixture in an amount of about 50 mol % to about 70 mol %. In some embodiments, the acrylate-based monomer may be present in the monomer mixture in an amount of about 50 mol %, about 70 mol %, about 72.42 mol % or about 48.4 mol %.

Additionally, when used (i.e., when present in an amount greater than 0 mol %), the triacrylate monomer may be present in the monomer mixture in an amount of about 5 mol % to about 10 mol %. However, it is understood that the triacrylate monomer may not be present in the monomer mixture, and therefore, in some embodiments, the triacrylate monomer may be present in the monomer mixture in any amount of about 0 mol % to about 10 mol %. In some embodiments, the triacrylate monomer may be present in the monomer mixture in an amount of about 7 mol % to about 9 mol %. For example, in some embodiments, the triacrylate monomer may be present in the monomer mixture in an amount of about 8 mol % to about 9 mol %. In some embodiments, the triacrylate monomer may be present in the monomer mixture in an amount of about 8.4 mol %.

Also, when used (i.e., when present in an amount greater than 0 mol %), the diacrylate monomer may be present in the monomer mixture in an amount of about 20 mol % to about 70 mol %. However, it is understood that the diacrylate monomer may not be present in the monomer mixture, and therefore, in some embodiments, the diacrylate monomer may be present in the monomer mixture in any amount of about 0 mol % to about 70 mol %. In some embodiments, the diacrylate monomer may be present in the monomer mixture in an amount of about 30 mol % to about 70 mol %. For example, in some embodiments, the diacrylate monomer may be present in the monomer mixture in an amount of about 30 mol % to about 60 mol %. In some embodiments, for example, the diacrylate monomer may be present in the monomer mixture in an amount of about 30 mol %, about 50 mol %, about 51.6 mol %, about 60 mol % or about 70 mol %.

In addition, when used (i.e., when present in an amount greater than 0 mol %), the mono-acrylate monomer may be present in the monomer mixture in an amount of about 5 mol % to about 30 mol %. However, it is understood that the mono-acrylate monomer may not be present in the monomer mixture, and therefore, in some embodiments, the mono-acrylate monomer may be present in the monomer mixture in any amount of about 0 mol % to about 30 mol %. In some embodiments, the mono-acrylate monomer may be present in the monomer mixture in an amount of about 7 mol % to about 20 mol %. For example, in some embodiments, the mono-acrylate monomer may be present in the monomer mixture in an amount of about 7 mol % to about 15 mol %. In some embodiments, the mono-acrylate monomer may be present in the monomer mixture in an amount of about 10 mol %.

In some embodiments, the curable resin composition may further include a polymerization initiator. Any suitable polymerization initiator may be used, and the polymerization initiator may be selected based on the polymerization mechanism used. The polymerization mechanism is not particularly limited, and may be, for example, UV radiation, thermal cure, or electron beam treatment, but the polymerization mechanism is not limited thereto. In some embodiments, for example when the curable resin composition is deposited on a substrate by flash evaporation or vacuum deposition, the polymerization mechanism may include UV radiation or electron beam treatment. In other embodiments, for example when the curable resin is deposited on a substrate by non-vacuum deposition means (e.g., inkjet printing, spin coating, screen printing, blade coating, bar coating, etc.), the polymerization mechanism may include thermal cure, UV radiation or electron beam treatment.

In embodiments in which the polymerization mechanism includes thermal cure, the polymerization initiator may include any initiator suitable for effecting cross-linking through the application of heat. Various compounds suitable for use as such an initiator are known in the art, and those of ordinary skill in the art would be capable of selecting a suitable initiator based on the desired performance and/or application of the curable resin composition. For example, any thermal initiator capable of initiating a curing reaction at a temperature of about 100° C. to about 150° C. can be used. Some nonlimiting examples of suitable such initiators include azobisisobutyronitrile, and peroxides, such as, benzoyl peroxide, dilauroyl peroxide, dicumyl peroxide.

In embodiments in which the polymerization mechanism includes UV radiation or electron beam treatment, the polymerization initiator may include a photoinitiator. Various compounds suitable for use as photoinitiators are known in the art, and those of ordinary skill in the art would be capable of selecting a suitable photoinitiator based on the curing mechanism and its parameters (e.g., the wavelength and/or power of the UV source) as well as the desired performance and/or application of the curable resin composition. For example, in some embodiments, the photoinitiator may include a compound capable of initiating a curing reaction when exposed to a UV wavelength of about 400 nm from an LED lamp or a UV wavelength of about 254 nm from a low-pressure Hg lamp. Some nonlimiting examples of suitable photoinitiators include 2,4,6-trimethylbenzoyl diphenyl phosphine oxide, hydroxy-cyclohexyl-phenyl-ketone, bis(2,4,6-trimethylbenzoyl)-phenyl phosphine oxide, 2,2-diethoxyacetophenone, and trimethylbenzophenone/methylbenzophenone. For example, in some embodiments, 2,4,6-trimethylbenzoyl diphenyl phosphine oxide, hydroxy-cyclohexyl-phenyl-ketone, and bis(2,4,6-trimethylbenzoyl)-phenyl phosphine oxide may be used when the UV source is a LED lamp emitting a wavelength of about 400 nm, and 2,2-diethoxyacetophenone, and trimethylbenzophenone/methylbenzophenone may be used when the UV source is a low pressure Hg lamp emitting a wavelength of about 254 nm.

The polymerization initiator may be present in the curable resin composition in an amount of about 2 wt % to about 10 wt % based on the total weight of the curable resin composition. For example, in some embodiments, the polymerization initiator may be present in the curable resin composition in an amount of about 3 wt % to about 7 wt % based on the total weight of the curable resin composition. In some embodiments, the polymerization initiator may be present in an amount of about 4 wt % to about 6 wt %, for example, about 4.5 wt % based on the total weight of the curable resin composition.

In an example embodiment, a curable resin composition may include about 4.5 wt % of a polymerization initiator (e.g., 2,4,6-trimethyolbenzoyldiphenyl phosphine oxide), and about 95.5 wt % of a monomer mixture including about 10 mol % of a monofunctional acrylate (e.g., lauryl acrylate), about 60 mol % of a difunctional acrylate (e.g., dodecyl dimethacrylate), and about 30 mol % of a siloxane monomer (e.g., a monomer represented by one of Formula 2 through 6, above).

According to another example, a curable resin composition may include about 4.5 wt % of a polymerization initiator (e.g., 2,4,6-trimethyolbenzoyldiphenyl phosphine oxide), and about 95.5 wt % of a monomer mixture including about 10 mol % of a monofunctional acrylate (e.g., lauryl acrylate), about 51.6 mol % of a difunctional acrylate (e.g., dodecyl dimethacrylate), about 8.4 mol % of a trifunctional acrylate (e.g., trimethylolpropane triacrylate) and about 30 mol % of a siloxane monomer (e.g., a monomer represented by one of Formula 2 through 6, above).

According to another example, a curable resin composition may include about 4.5 wt % of a polymerization initiator (e.g., 2,4,6-trimethyolbenzoyldiphenyl phosphine oxide), and about 95.5 wt % of a monomer mixture including about 10 mol % of a monofunctional acrylate (e.g., lauryl acrylate), about 51.6 mol % of a difunctional acrylate (e.g., dodecyl dimethacrylate), about 8.4 mol % of a trifunctional acrylate (e.g., trimethylolpropane triacrylate) and about 30 mol % of a siloxane monomer (e.g., a monomer represented by one of Formulae 2 through 6, above).

In another example embodiment, a curable resin composition may include about 4.5 wt % of a polymerization initiator (e.g., 2,4,6-trimethyolbenzoyldiphenyl phosphine oxide), and about 95.5 wt % of a monomer mixture including about 10 mol % of a monofunctional acrylate (e.g., lauryl acrylate), about 30 mol % of a difunctional acrylate (e.g., dodecyl dimethacrylate), about 8.4 mol % of a trifunctional acrylate (e.g., trimethylolpropane triacrylate), and about 51.6 mol % of a siloxane monomer (e.g., a monomer represented by Formula 3, above).

According to another example, a curable resin composition may include about 4.5 wt % of a polymerization initiator (e.g., 2,4,6-trimethyolbenzoyldiphenyl phosphine oxide), and about 95.5 wt % of a monomer mixture including about 70 mol % of a difunctional acrylate (e.g., dodecyl dimethacrylate), and about 30 mol % of a siloxane monomer (e.g., a monomer represented by one of Formula 2 through 6, above).

In another example, a curable resin composition may include about 4.5 wt % of a polymerization initiator (e.g., 2,4,6-trimethyolbenzoyldiphenyl phosphine oxide), and about 95.5 wt % of a monomer mixture including about 50 mol % of a difunctional acrylate (e.g., dodecyl dimethacrylate) and about 50 mol % of a siloxane monomer (e.g., a monomer represented by one of Formula 2 through 6, above).

The curable resin composition may be deposited on a substrate, or as discussed in further detail below, directly on a device (e.g., an organic light emitting device (OLED)). The curable resin composition may be deposited by any suitable deposition technique, including, but not limited to, vacuum deposition techniques, flash evaporation, and non-vacuum deposition techniques. For example, in some embodiments, the curable resin composition is deposited by flash evaporation. In other embodiments, the curable resin composition may be deposited by a non-vacuum deposition technique, such as, for example, inkjet printing, screen printing, spin coating, blade coating, bar coating, etc. In some embodiments, for example, the curable resin composition may be deposited by inkjet printing. The curable resin composition may be deposited on an entire surface of the substrate or device, or may be depositing only on select areas of the substrate or device. The substrate may be any suitable substrate, for example, a plastic foil.

The curable resin compositions according to embodiments of the present invention exhibit improved resistance to plasma compared to traditional polymers used for decoupling layers in a barrier stack structure. In addition to improved plasma resistance, the curable resin composition according to embodiments of the present invention exhibits good transparency in the visible and UV/vis spectra. Moreover, the curable resin compositions according to embodiments of the present invention exhibit good wettability of the underlying substrate (or device), enabling the manufacture of a substantially uniform, smooth film. As used herein, the term “substantially” is used as a term of approximation, and not as a term of degree, and is intended to account for inherent, standard deviations in measured or calculated values, as would be understood by those of ordinary skill in the art.

According to some embodiments of the present invention, a barrier stack includes a decoupling (or smoothing/planarization) layer and a barrier layer. In some embodiments, the barrier stack may include additional decoupling layers and additional barrier layers arranged in dyads. A dyad is a coupling of a decoupling layer and a barrier layer, and when a barrier stack includes multiple dyads, the resulting barrier stack structure includes alternating layers of decoupling layers and barrier layers such that the barrier layer of a first dyad is on the decoupling layer of the first dyad, the decoupling layer of the second dyad is on the barrier layer of the first dyad, the barrier layer of the second dyad is on the decoupling layer of the second dyad, and so on. The layers of the barrier stack can be directly deposited on a device to be encapsulated (or protected) by the barrier stack, or may be deposited on a separate substrate or support, and then laminated on the device. The decoupling layer(s) of the barrier stack serves as a planarization, decoupling and/or smoothing layer, and may include a siloxane containing resin composition, for example derived from the curable resin composition described above. To form the decoupling layer of the barrier stack, the curable resin composition is applied to the substrate (or device, or underlying barrier layer of a prior dyad), and cured, e.g., by heat, UV radiation or electron beam treatment. By virtue of the curing procedure, the siloxane containing resin composition of the decoupling layer includes a moiety derived from the siloxane monomer in the curable resin composition described above. For example, upon curing, the cured (or cross-linked) siloxane containing resin composition includes a moiety derived from a siloxane monomer represented by Formula 1, above.

The curable resin composition may be deposited on the device or substrate by any suitable deposition technique, some nonlimiting examples of which include vacuum processes and atmospheric processes. Some nonlimiting examples of suitable vacuum processes for deposition of the decoupling layer include flash evaporation, and can include any suitable polymerization technique, such as thermal curing, or in situ polymerization under vacuum, and plasma deposition and polymerization. Some nonlimiting examples of suitable atmospheric processes for deposition of the decoupling layer include spin coating, ink jet printing, screen printing and spraying. In some embodiments, the decoupling layer may be applied to the substrate (or support), device, or underlying barrier layer by flash evaporation followed by curing, or ink jet printing.

The decoupling layer can have any suitable thickness such that the layer has a substantially planar and/or smooth layer surface. As used herein, the term “substantially” is used as a term of approximation and not as a term of degree, and is intended to account for normal variations and deviations in the measurement or assessment of the planar or smooth characteristic of the decoupling layer. In some embodiments, for example, the decoupling layer has a thickness of about 100 to about 1000 nm.

According to embodiments of the present invention, the barrier stack also include a barrier layer, which serves to prevent or reduce the permeation of damaging gases, liquids and chemicals to the encapsulated or protected device. The barrier layer is deposited on the decoupling layer, and deposition of the barrier layer may vary depending on the material used for the barrier layer. However, in general, any deposition technique and any deposition conditions can be used to deposit the barrier layer. For example, the barrier layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, or a combination thereof. In some embodiments, for example, the barrier layer is deposited by sputtering, for example, AC sputtering.

The material of the barrier layer is not particularly limited, and may be any material suitable for substantially preventing or reducing the permeation of damaging gases, liquids and chemicals (e.g., oxygen and water vapor) to the encapsulated or protected device. Some nonlimiting examples of suitable materials for the barrier layer include metals, metal oxides, metal nitrides, metal oxynitrides, metal carbides, metal oxyborides, and combinations thereof. Those of ordinary skill in the art would be capable of selecting a suitable metal for use in the oxides, nitrides and oxynitrides based on the desired properties of the layer. However, in some embodiments, for example, the metal may be Al, Zr, Si or Ti.

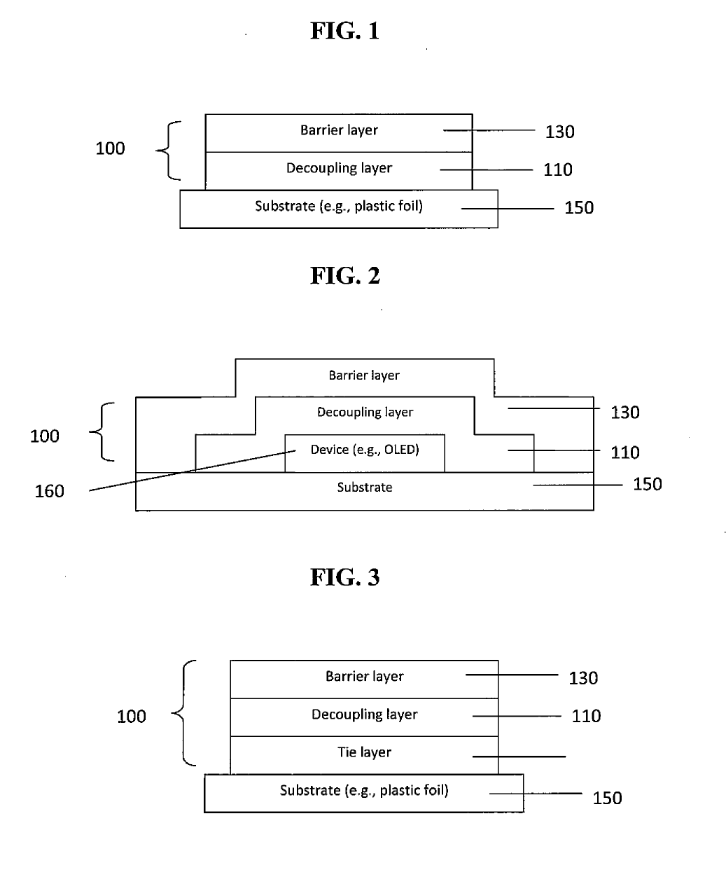

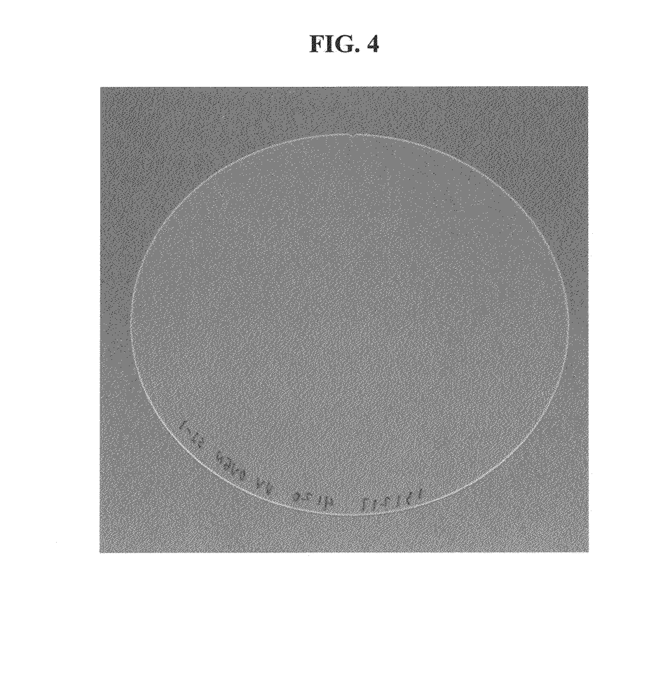

Exemplary embodiments of a barrier stack according to the present invention are illustrated in FIGS. 1 and 2. The barrier stack 100 depicted in FIG. 1 includes a decoupling layer 110 which includes a polymer cured from the curable resin composition described above, and a barrier layer 130 which includes an oxide barrier layer. In FIG. 1, the barrier stack 100 is deposited on a substrate 150, for example glass. However, in FIG. 2, the barrier stack 100 is deposited directly on the device 160 to be protected, e.g., an organic light emitting device.

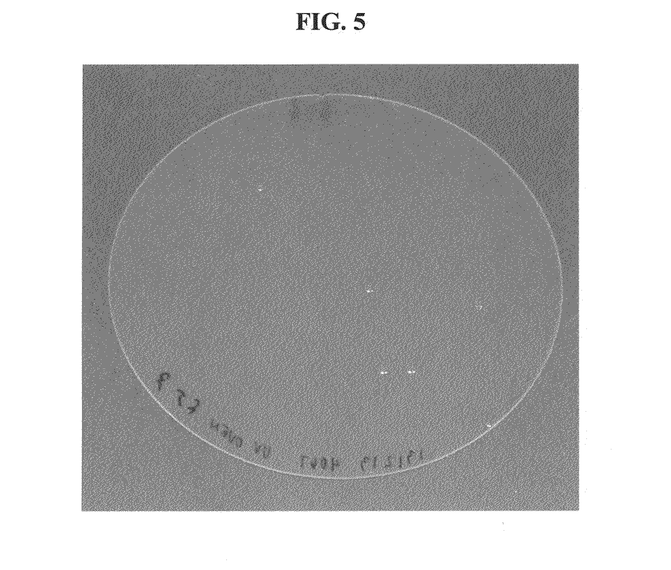

In addition to the decoupling layer 110 and the barrier layer 130, some exemplary embodiments of the barrier stack 100 can include a tie layer 140 between the decoupling layer 110 and the substrate 150 or the device 160 to be encapsulated. Although the barrier stacks are depicted in the accompanying drawings as including a tie layer 140, decoupling layer 110 and barrier layer 130, it is understood that these layers may be deposited on the substrate 150 or the device 160 in any order, and the depiction of these layers in a particular order in the drawings does not mean that the layers must be deposited in that order. Indeed, as discussed here, and depicted in FIG. 3, the tie layer 140 may be deposited on the substrate 150 or device 140 prior to deposition of the decoupling layer 110.

The tie layer 140 acts to improve adhesion between the layers of the barrier stack 100 and the substrate 150 or the device 160 to be encapsulated. The material of the tie layer 140 is not particularly limited, and can include the materials described above with respect to the barrier layer. Also, the material of the tie layer may be the same as or different from the material of the barrier layer. The material of the barrier layer is described above.

Additionally, the tie layer may be deposited on the substrate or the device to be encapsulated by any suitable technique, including, but not limited to the techniques described above with respect to the barrier layer. In some embodiments, for example, the tie layer may be deposited by sputtering, for example AC sputtering, under conditions similar to those described above for the barrier layer. Also, the thickness of the deposited tie layer is not particularly limited, and can be any thickness suitable to effect good adhesion between the decoupling layer of the barrier stack and the substrate or device to be encapsulated. In some embodiments, for example, the tie layer can have a thickness of about 20 nm to about 60 nm, for example, about 40 nm.

An exemplary embodiment of a barrier stack 100 according to the present invention including a tie layer 140 is depicted in FIG. 3. The barrier stack 100 depicted in FIG. 3 includes a decoupling layer 110 which includes a polymer cured from the curable resin composition described above, a tie layer 140 which includes an oxide layer, and a barrier layer 130 which includes an oxide barrier layer. In FIG. 3, the barrier stack 100 is deposited on a substrate 150, for example glass. However, it is understood that the barrier stack 100 can alternatively be deposited directly on the device 160, e.g., an organic light emitting device, as depicted in FIG. 2 with respect to the embodiments excluding the tie layer.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a decoupling layer 110 on the substrate. The decoupling layer 110 includes a cured polymer formed from the curable resin composition described above and provides a smooth and/or planar surface for the subsequent deposition of the barrier layer. As also discussed above, the decoupling layer 110 may be deposited on the device 160 or substrate 150 by any suitable deposition technique, including, but not limited to, vacuum processes and atmospheric processes. Some nonlimiting examples of suitable vacuum processes for deposition of the decoupling layer include flash evaporation with thermal curing or in situ polymerization under vacuum, and plasma deposition and polymerization. Some nonlimiting examples of suitable atmospheric processes for deposition of the first layer include spin coating, ink jet printing, screen printing and spraying. For example, in some embodiments, the decoupling layer is formed on the substrate or device by flash evaporation with thermal curing or by ink jet printing.

The method further includes depositing a barrier layer 130 on the surface of the decoupling layer 120. The barrier layer 130 is as described above and acts as the barrier layer of the barrier stack, serving to substantially prevent or substantially reduce the permeation of damaging gases, liquids and chemicals to the underlying device. The deposition of the barrier layer 130 may vary depending on the material used for the barrier layer. However, in general, any deposition technique and any deposition conditions can be used to deposit the barrier layer. For example, the barrier layer 130 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, or a combination thereof. In some embodiments, however, the barrier layer 130 may be deposited by AC sputtering.

In some embodiments, the method further includes depositing a tie layer 140 between the substrate 150 (or the device 160 to be encapsulated) and the decoupling layer 110. The tie layer 140 is as described above and serves to improve adhesion between the substrate or device and the decoupling layer 110 of the barrier stack 100. The tie layer 140 may be deposited by any suitable technique, as discussed above. For example, as also discussed above, the tie layer 140 may be deposited on the substrate 150 (or the device 160 to be encapsulated) by any suitable technique. In some embodiments, for example, the tie layer 140 is deposited by AC sputtering, as discussed above.

The following Examples are provided for illustrative purposes only and do not limit the scope of any embodiments of the present invention.

### Example 1

### Synthesis of 1,5-bis(acryloxypropyl)-1,1-5,5-tetramethyl-3,3-diphenyl trisiloxane Represented by Formula 2a

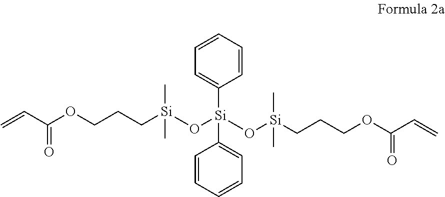 [SMILES: C=CC(=O)OCCC[Si](C)(C)O[Si](O[Si](C)(C)CCCOC(=O)C=C)(c1ccccc1)c1ccccc1]

1.96 g of diphenylsilanediol, 2.94 g of 1,3-bis(acryloxypropyl)-1,1,3,3-tetramethyldisiloxane, and 0.303 g of p-toluenesulfonic acid were added to a 20 mL glass vial. The mixture was shaken thoroughly for 26 hours, and then dissolved in 42.7 g of toluene and washed 11 times in a separatory funnel with deionized water. The toluene was removed by rotary evaporation to produce 1,5-bis(acryloxypropyl)-1,1,5,5-tetramethyl-3,3-diphenyl trisiloxane with an 80% yield.

Synthesis schemes for the compounds represented by Formulae 3 and 4 would be recognized by those of ordinary skill in the art based on the synthesis described in the above Example 1.

### Example 2

### Synthesis of Curable Resin Composition

95.5 wt % of a monomer mixture was mixed with 4.5 wt % of a photoinitiator to prepare a curable resin composition. The monomer mixture included 10 mol % lauryl acrylate, 60 mol % dodecyl dimethacrylate, and 30 mol % 1,5-bis(acryloxypropyl)-1,1-5,5-tetramethyl-3,3-diphenyl trisiloxane represented by Formula 2 (i.e., the monomer produced in Example 1). The photoinitiator was 2,4,6-trimethylolbenzoyldiphenylphosphine oxide.

### Example 3

### Synthesis of Curable Resin Composition

95.5 wt % of a monomer mixture was mixed with 4.5 wt % of a photoinitiator to prepare a curable resin composition. The monomer mixture included 10 mol % lauryl acrylate, 51.6 mol % dodecyl dimethacrylate, 8.4 mol % trimethylol propane triacrylate, and 30 mol % 1,5-bis(acryloxypropyl)-1,1-5,5-tetramethyl-3,3-diphenyl trisiloxane represented by Formula 2 (i.e., the monomer produced in Example 1). The photoinitiator was 2,4,6-trimethylolbenzoyldiphenylphosphine oxide.

### Example 4

### Synthesis of Curable Resin Composition

95.5 wt % of a monomer mixture was mixed with 4.5 wt % of a photoinitiator to prepare a curable resin composition. The monomer mixture included 10 mol % lauryl acrylate, 60 mol % dodecyl dimethacrylate, and 30 mol % 1,5-bis(acryloxypropyl)-1,1,3,5,5-pentamethyl-3-phenyl trisiloxane represented by Formula 3a. The photoinitiator was 2,4,6-trimethylolbenzoyldiphenylphosphine oxide.

### Example 5

### Synthesis of Curable Resin Composition

95.5 wt % of a monomer mixture was mixed with 4.5 wt % of a photoinitiator to prepare a curable resin composition. The monomer mixture included 10 mol % lauryl acrylate, 51.6 mol % dodecyl dimethacrylate, 8.4 mol % trimethylol propane triacrylate, and 30 mol % 1,5-bis(acryloxypropyl)-1,1,3,5,5-pentamethyl-3-phenyl trisiloxane represented by Formula 3a. The photoinitiator was 2,4,6-trimethylolbenzoyldiphenylphosphine oxide.

### Example 6

### Synthesis of Curable Resin Composition

95.5 wt % of a monomer mixture was mixed with 4.5 wt % of a photoinitiator to prepare a curable resin composition. The monomer mixture included 10 mol % lauryl acrylate, 30 mol % dodecyl dimethacrylate, 8.4 mol % trimethylol propane triacrylate, and 51.6 mol % 1,5-bis(acryloxypropyl)-1,1,3,5,5-pentamethyl-3-phenyl trisiloxane represented by Formula 3a. The photoinitiator was 2,4,6-trimethylolbenzoyldiphenylphosphine oxide.

### Example 7

### Synthesis of Curable Resin Composition

95.5 wt % of a monomer mixture was mixed with 4.5 wt % of a photoinitiator to prepare a curable resin composition. The monomer mixture included 10.35 mol % lauryl acrylate, 62.07 mol % dodecyl dimethacrylate, and 27.58 mol % 1,9-bis(acryloxypropyl)-1,1,3,3,5,5,7,7,9,9-decamethyl hexasiloxane represented by Formula 4a. The photoinitiator was 2,4,6-trimethylolbenzoyldiphenylphosphine oxide.

### Example 8

### Synthesis of Curable Resin Composition

95.5 wt % of a monomer mixture was mixed with 4.5 wt % of a photoinitiator to prepare a curable resin composition. The monomer mixture included 10 mol % lauryl acrylate, 60 mol % dodecyl dimethacrylate, and 30 mol % 1,9-bis(acryloxypropyl)-1,1,3,3,5,5,7,7,9,9-decamethyl hexasiloxane represented by Formula 4a. The photoinitiator was 2,4,6-trimethylolbenzoyldiphenylphosphine oxide.

### Example 9

### Synthesis of Curable Resin Composition

95.5 wt % of a monomer mixture was mixed with 4.5 wt % of a photoinitiator to prepare a curable resin composition. The monomer mixture included 10 mol % lauryl acrylate, 51.6 mol % dodecyl dimethacrylate, 8.4 mol % trimethylol propane triacrylate, and 30 mol % 1,9-bis(acryloxypropyl)-1,1,3,3,5,5,7,7,9,9-decamethyl hexasiloxane represented by Formula 4a. The photoinitiator was 2,4,6-trimethylolbenzoyldiphenylphosphine oxide.

### Comparative Example 1

### Synthesis of Curable Resin Composition

95.5 wt % of a monomer mixture was mixed with 4.5 wt % of a photoinitiator to prepare a curable resin composition. The monomer mixture included 22.5 mol % lauryl acrylate, 67.5 mol % dodecyl dimethacrylate, and 8.4 mol % trimethylol propane triacrylate. The photoinitiator was 2,4,6-trimethylolbenzoyldiphenylphosphine oxide.

### Testing Results

A barrier stack prepared using the curable resin composition according to Example 5 to prepare the decoupling layer was tested to determine the water vapor transmission rate (WVTR). Specifically, two test substrates were prepared, each of which was prepared by depositing six calcium coupons on a glass substrate, depositing the curable resin composition of Example 5 on the calcium coupons, curing the curable resin composition, depositing an aluminum oxide barrier layer on the resulting cured polymer decoupling layer, and depositing a protective polymer on the barrier layer. The oxide barrier layer on the first of the two substrates was deposited by pulsed DC sputtering, and the oxide barrier layer on the second of the two substrates was deposited by pulsed AC sputtering. The WVTR of each of the coupons was tested over time under room temperature and humidity conditions and under an environment at 85° C. and 85% Relative humidity. The calcium test procedures are described in Nisato, et al. “P-88: Thin Film Encapsulation for OLEDs: Evaluation of Multi-Layer Barriers using the Ca Test,” SID 03 Digest, ISSN/0003-0966X/03/3401-0550, pg. 550-553 (2003)(describing the calcium test procedure) and Nisato, et al., “Evaluating High Performance Diffusion Barriers: the Calcium Test,” Proc. Asia Display, IDW01, pg. 1435 (2001) (also describing the calcium test), the entire contents of all of which are incorporated herein by reference.

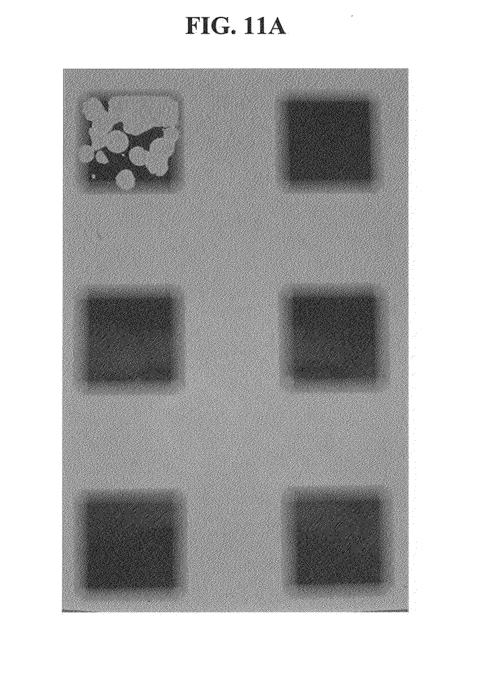

FIGS. 10A and 10B are graphs of the WVTR of the coupons over time, with FIG. 10A showing the WVTR over time of the coupons (labeled B (dark blue), C (pink), D (yellow), F (aqua), G (purple) and H (dark red)) on which the barrier layer was deposited by pulsed DC sputtering, and FIG. 10B showing the WVTR over time of the coupons on which the barrier layer was deposited by pulsed AC sputtering. As can be determined from these graphs, there is not a significant difference between AC and DC sputtering. The average WVTR at room temperature and humidity was about 3.55×10⁻⁷ g/m²/day, and the average WVTR at 85° C. and 85% Relative Humidity was about 3.87×10⁻⁵ g/m²/day, indicating minimal or no plasma damage to the decoupling layer.

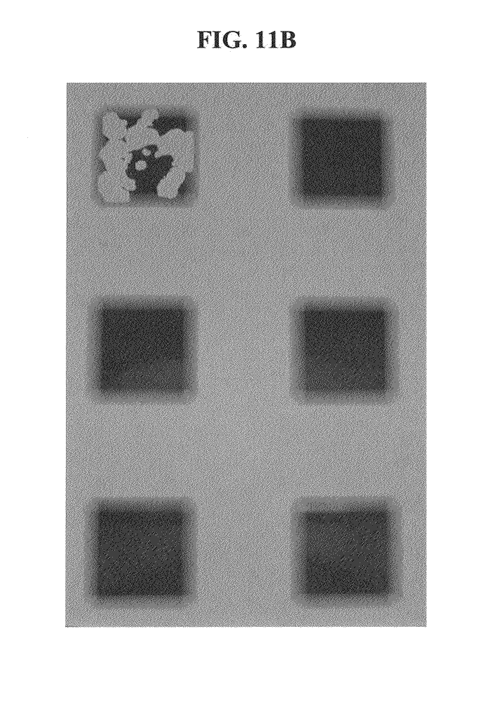

Additionally, FIGS. 11A and 11B are photographs of the two substrates with the calcium coupons 500 hours after barrier deposition. As can be seen from these photographs, five of the six calcium coupons show virtually no damage or defect. While the sixth coupon shows some damage, the damage to this coupon was likely the result of an error in the preparation of that coupon, and the results seen in the other five coupons on each substrate shows that the decoupling layers prepared from the curable resin composition of Example 5 exhibits good plasma damage resistance.

Examples 4 and 5 and Comparative Example 1 were evaluated for conversion of C═C bonds after cure. The conversion evaluation of Examples 4 and 5 and Comparative Example 1 compared the ratio of C═C bonds to C═O bonds in the curable resin composition (i.e., in liquid form) to the same ratio after cure. The conversion rates for Examples 4 and 5, and Comparative Example 1 under cure conditions of 15% power of a 100 mW/cm² at a track speed of 150 cm/min were 95.5%, 88.5% and 84.1±3%, respectively. The conversion rates for Examples 4 and 5, and Comparative Example 1 under cure conditions of 30% power of a 200 mW/cm² at a track speed of 75 cm/min were 99.4%, 91.5% and 90.5±2%, respectively. As can be seen from this comparison, Examples 4 and 5 including a siloxane monomer according to embodiments of the present invention exhibit improved conversion rates over the curable resin composition of Comparative Example 1, which did not include a siloxane monomer.

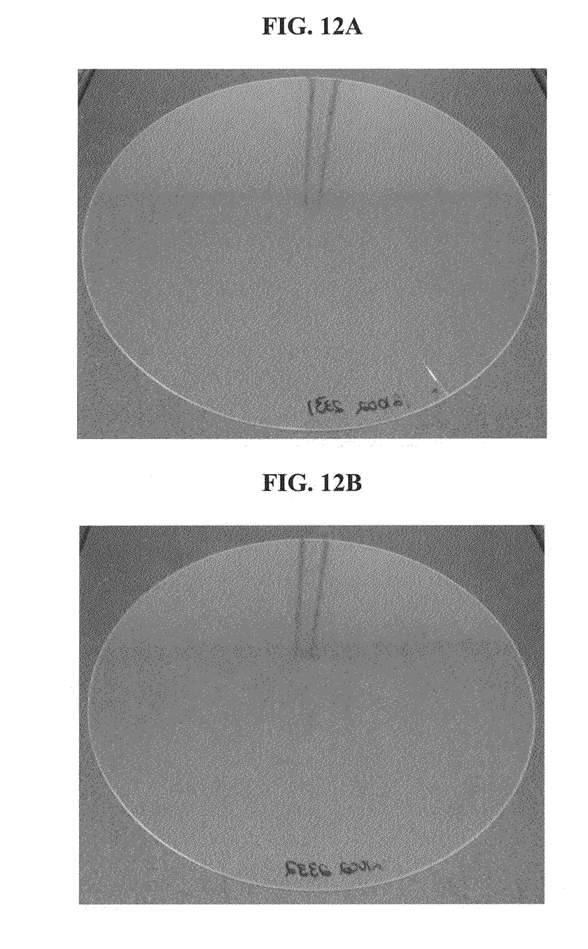

Example 4 was evaluated for plasma damage to the cured polymer after deposition of the barrier layer by pulsed DC sputtering and pulsed AC sputtering. In particular, two samples were prepared by depositing the curable resin composition of Example 4 on each of two glass substrates and cured, and then a 100 nm aluminum oxide barrier layer was deposited on the first substrate over the cured polymer layer by pulsed DC sputtering, and an aluminum oxide barrier layer was deposited on the second substrate over the cured polymer layer by pulsed AC sputtering. The pulsed DC sputtering was performed at a power of 3.2 kW, a pressure of 2.5 mTorr, an Ar flow rate of 65 sccm, and a track speed of 70 cm/min. The pulsed AC sputtering was performed at a power of 4 kW, a pressure of 4.5 mTorr, an Ar flow rate of 100 sccm, and a track speed of 70 cm/min. After deposition of the aluminum oxide layer, each substrate was placed in a UV oven and exposed to UV for 20 minutes. FIGS. 12A and 12B are photographs of the glass substrates after UV exposure, with FIG. 12A showing the glass substrate on which the oxide layer was deposited by DC sputtering, and FIG. 12B showing the glass substrate on which the oxide layer was deposited by AC sputtering. As can be seen in FIGS. 12A and 12B, both the substrates exhibit good plasma damage resistance, and there does not appear to be a discernible difference in plasma damage resistance performance based on deposition by DC or AC sputtering.

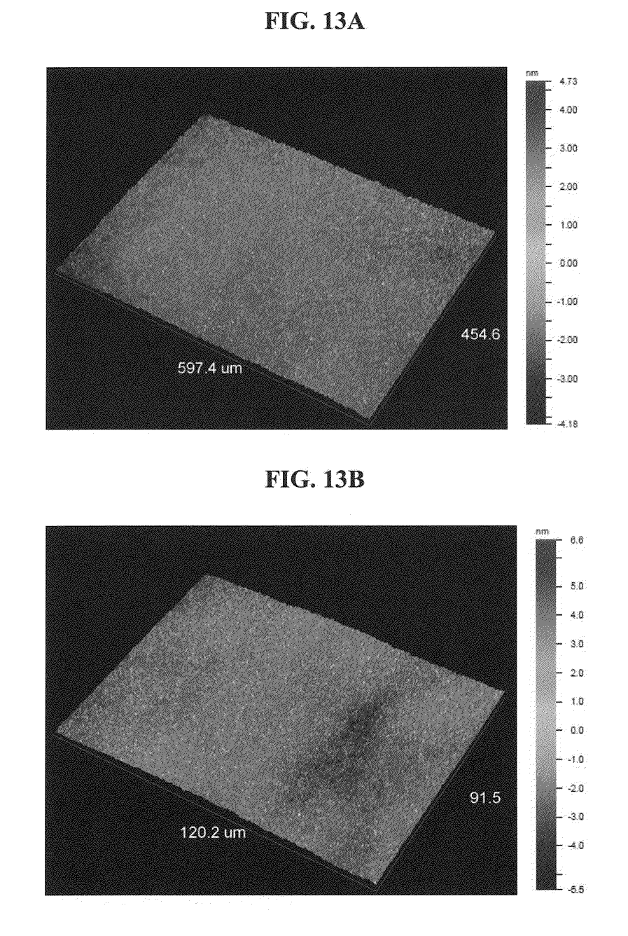

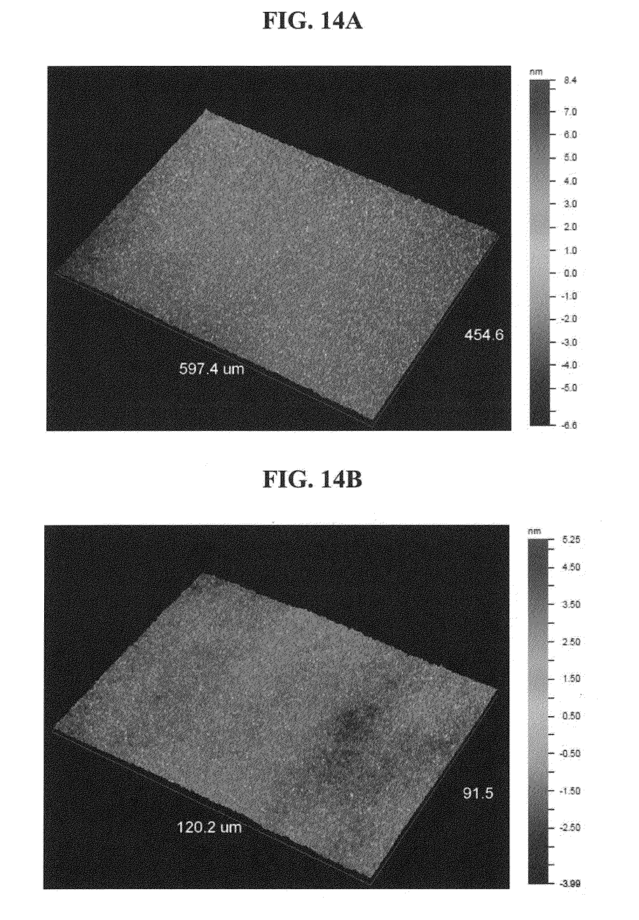

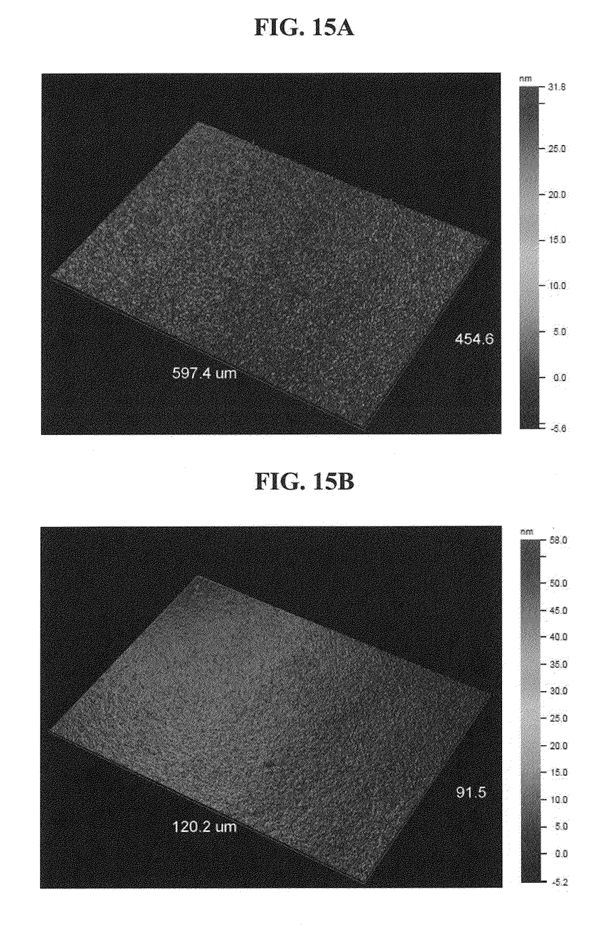

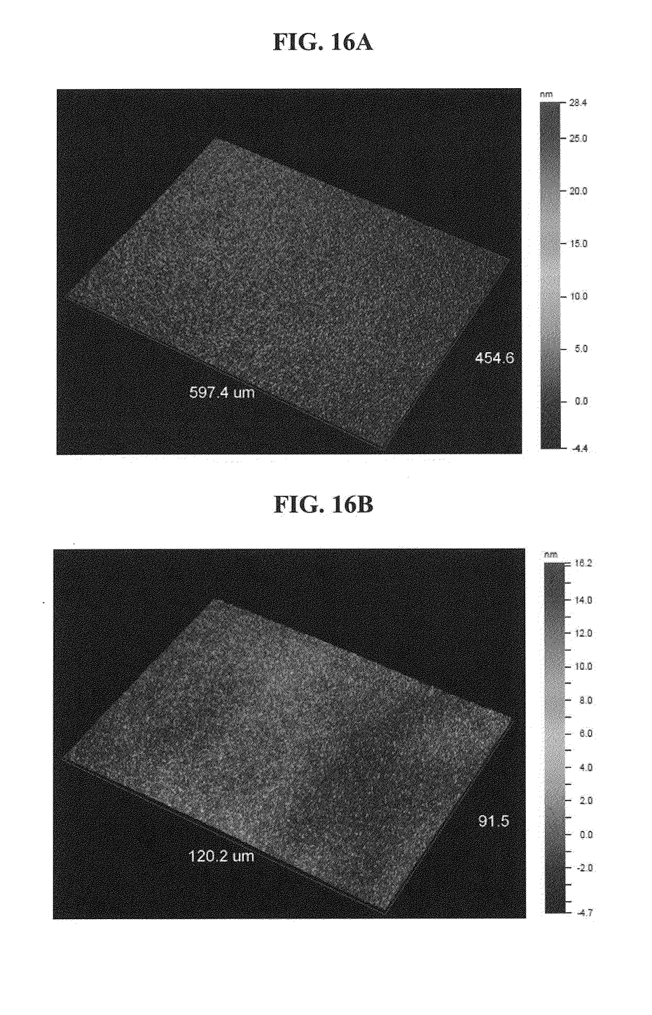

Example 5 was evaluated for morphological stability by observing the surface smoothness after deposition and after aging under specific atmospheric conditions. In particular, a barrier structure including a glass substrate, a 40 nm first oxide layer on the glass substrate, a 1 μm first polymer layer (using Example 5) on the first oxide layer, a 40 nm second oxide layer on the first oxide layer, and a 1 μm second polymer layer (using Example 5) on the second oxide layer. The stacks were evaluated for surface morphology after deposition, after exposure in an 85° C. dry oven for 139 hours, after exposure in a 40° C. oven at 90% relative humidity for 139 hours, and after exposure in an 85° C. oven at 85% relative humidity for 139 hours. FIGS. 13A and 13B are optical profilometry images of the stack after deposition at 10× (FIG. 13A) and 50× (FIG. 13B) magnification. FIGS. 14A and 14B are optical profilometry images of the stack after exposure in an 85° C. dry oven for 139 hours at 10× (FIG. 14A) and 50× (FIG. 14B) magnification. FIGS. 15A and 15B are optical profilometry images of the stack after exposure in a 40° C. oven at 90% relative humidity for 139 hours at 10× (FIG. 15A) and 50× (FIG. 15B) magnification. FIGS. 16A and 16B are optical profilometry images of the stack after exposure in an 85° C. oven at 85% relative humidity for 139 hours at 10× (FIG. 16A) and 50× (FIG. 16B) magnification. As can be seen from a comparison of FIGS. 13A, 14A, 15A and 16A, and a comparison of FIGS. 13B, 14B, 15B and 16B, the stacks made using the curable resin composition of Example 5 exhibited a smooth surface after deposition, and maintained the smooth surface after exposure in the dry oven and the ovens at different relative humidity levels. In particular, as can be seen from comparing FIGS. 13A and 14A, and comparing FIGS. 13B and 14B, the surfaces of the stacks maintain a generally continuous green color, with only slight amounts of blue and other colors, indicating conservation of the smooth character of the surface. Similarly, in comparing FIGS. 15A and 16A, and comparing FIGS. 15B and 16B, the surfaces of the stacks maintain a generally continuous blue color, with only slight amounts of green and other colors, indicating conservation of the smooth character of the surface.

### Example 10

### Synthesis of Curable Resin Composition

95.5 wt % of a monomer mixture was mixed with 4.5 wt % of a photoinitiator to prepare a curable resin composition. The monomer mixture included 50 mol % dodecyl dimethacrylate, 20 mol % and 30 mol % 1,5-bis(methacryloxypropyl)-1,1,5,5-tetramethyl-3,3-diphenyl trisiloxane represented by Formula 2b. The photoinitiator was 2,4,6-trimethylolbenzoyldiphenylphosphine oxide.

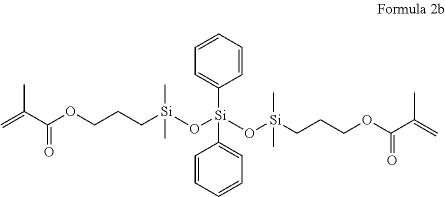 [SMILES: C=C(C)C(=O)OCCC[Si](C)(C)O[Si](O[Si](C)(C)CCCOC(=O)C(=C)C)(c1ccccc1)c1ccccc1]

### Example 11

### Synthesis of Curable Resin Composition

95.5 wt % of a monomer mixture was mixed with 4.5 wt % of a photoinitiator to prepare a curable resin composition. The monomer mixture included 50 mol % dodecyl dimethacrylate and 50 mol % 1,5-bis(acryloxypropyl)-1,1,3,3,5,5-hexamethyl trisiloxane represented by Formula 6a. The photoinitiator was 2,4,6-trimethylolbenzoyldiphenylphosphine oxide.

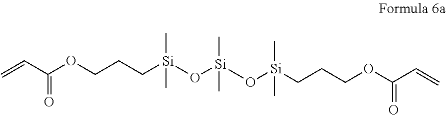 [SMILES: C=CC(=O)OCCC[Si](C)(C)O[Si](C)(C)O[Si](C)(C)CCCOC(=O)C=C]

### Example 12

### Synthesis of Curable Resin Composition

95.5 wt % of a monomer mixture was mixed with 4.5 wt % of a photoinitiator to prepare a curable resin composition. The monomer mixture included 50 mol % dodecyl dimethacrylate and 50 mol % 1,5-bis(acryloxypropyl)-1,1,3,5,5-pentamethyl-3-phenyl trisiloxane represented by Formula 3a. The photoinitiator was 2,4,6-trimethylolbenzoyldiphenylphosphine oxide.

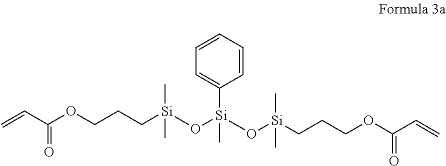 [SMILES: C=CC(=O)OCCC[Si](C)(C)O[Si](C)(O[Si](C)(C)CCCOC(=O)C=C)c1ccccc1]

### Example 13

### Synthesis of Curable Resin Composition

95.5 wt % of a monomer mixture was mixed with 4.5 wt % of a photoinitiator to prepare a curable resin composition. The monomer mixture included 50 mol % dodecyl dimethacrylate and 50 mol % 1,5-bis(methacryloxypropyl)-1,1,5,5-tetramethyl-3,3-diphenyl trisiloxane represented by Formula 2b. The photoinitiator was 2,4,6-trimethylolbenzoyldiphenylphosphine oxide.

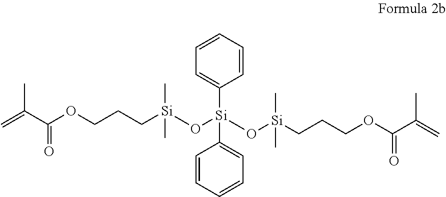 [SMILES: C=C(C)C(=O)OCCC[Si](C)(C)O[Si](O[Si](C)(C)CCCOC(=O)C(=C)C)(c1ccccc1)c1ccccc1]

### Example 14

### Synthesis of Curable Resin Composition

95.5 wt % of a monomer mixture was mixed with 4.5 wt % of a photoinitiator to prepare a curable resin composition. The monomer mixture included 30 mol % and 70 mol % 1,3-bis(3-acryloxypropyl)tetrakis(trimethylsiloxy)disiloxane as represented by Formula 5a. The photoinitiator was 2,4,6-trimethylolbenzoyldiphenylphosphine oxide.

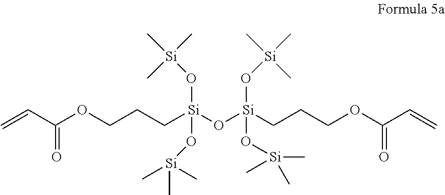 [SMILES: C=CC(=O)OCCC[Si](O[Si](C)(C)C)(O[Si](C)(C)C)O[Si](CCCOC(=O)C=C)(O[Si](C)(C)C)O[Si](C)(C)C]

### Comparative Example 2

95.5 wt % of a monomer mixture was mixed with 4.5 wt % of a photoinitiator to prepare a curable resin composition. The monomer mixture included 95 mol % dodecyl dimethacrylate and 5 mol % trimethylol propane triacrylate. The photoinitiator was 2,4,6-trimethylolbenzoyldiphenylphosphine oxide.

Each of the curable resin compositions of Examples 10-14 and Comparative Example 2 were tested for plasma damage resistance. In particular, each curable resin composition was deposited on a glass substrate by flash evaporation. In the flash evaporation process, the evaporator pressure was between 19 and 28 mtorr, the pump pressure was between 36 and 130 psi, the monomer flow rate was about 0.33 ml/min, and the track speed during deposition was about 60 cm/min. The flash evaporation resulted in film thicknesses of the curable resin compositions of about 8,000 nm to about 13,000 nm, indicating successful deposition and efficient deposition rates.

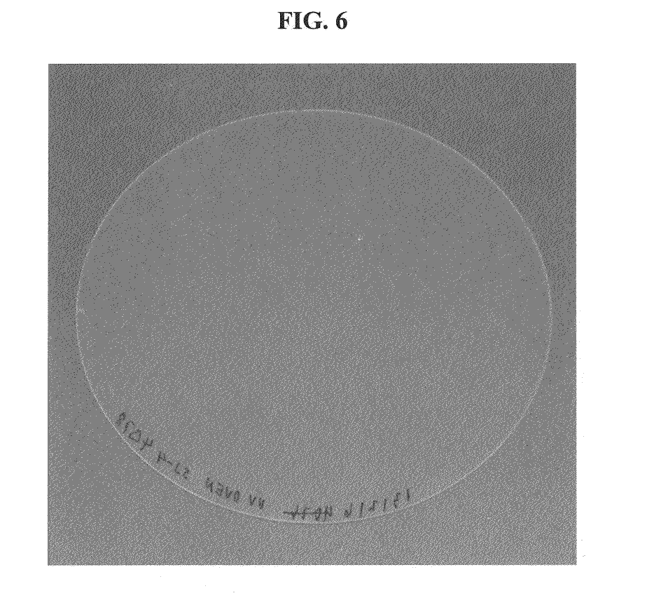

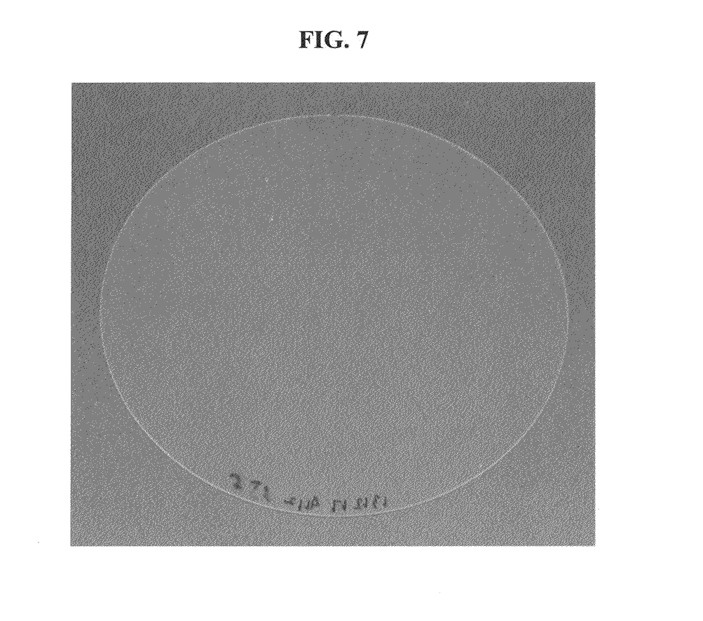

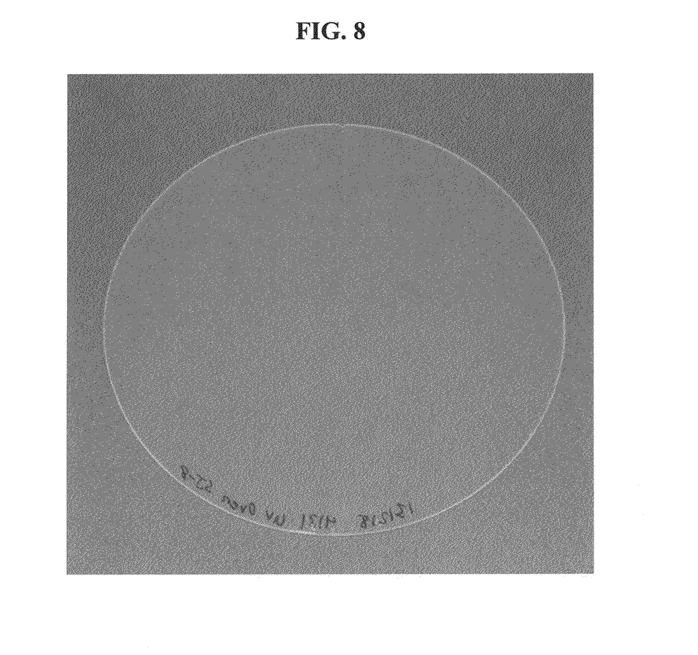

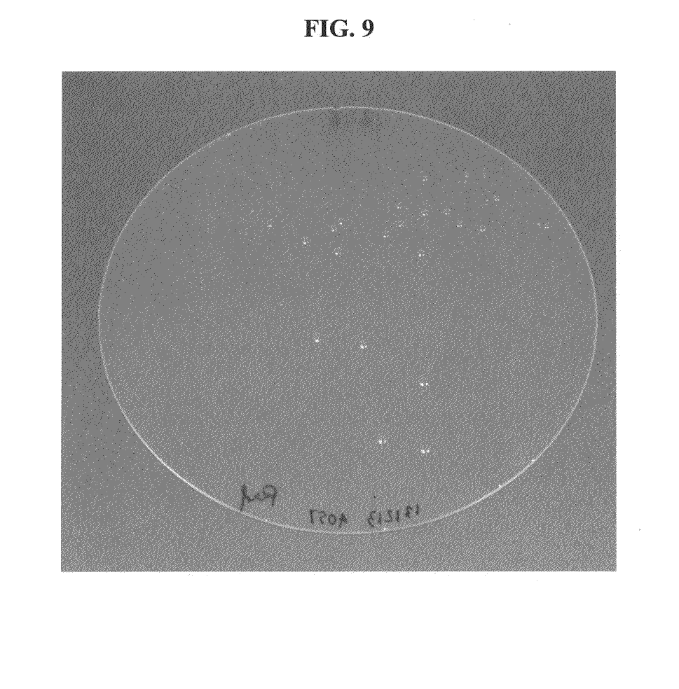

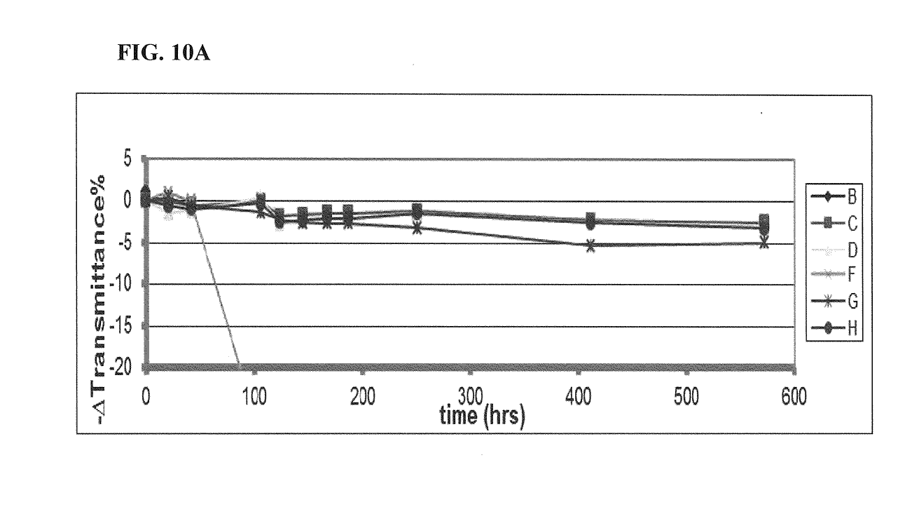

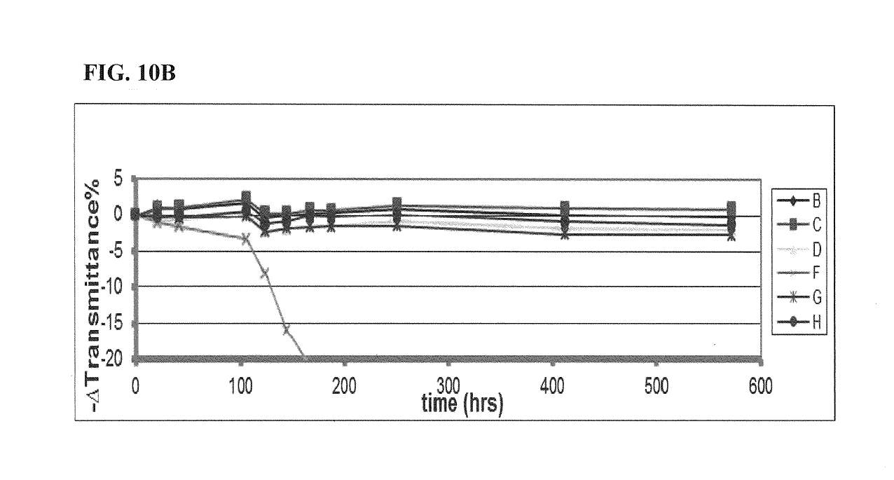

After evaporation onto the glass substrates, the curable resin compositions were cured, and an aluminum oxide barrier layer was deposited on the cured polymer layer by DC sputtering. The resulting substrate was placed in a UV oven and exposed to UV light for 20 minutes and then removed from the oven. The substrates were allowed to stand overnight, and then observed for bubble or defect formation. FIGS. 4 through 8 are photographs of the substrates (after UV exposure and rest time) prepared with the curable resin compositions of Examples 10 through 14, respectively, and FIG. 9 is a photograph of the substrate (after UV exposure and rest time) prepared with the curable resin composition of Comparative Example 2. As can be seen in FIGS. 4 through 9, the substrate prepared with the curable resin composition of Comparative Example 2 (as shown in FIG. 9) exhibited significantly more bubbling than the substrates prepared with the curable resin compositions of Examples 10 through 14. This indicates that decoupling layers prepared from the curable resin compositions including a siloxane monomer according to embodiments of the present invention have significantly improved plasma damage resistance.

While certain exemplary embodiments of the present invention have been illustrated and described, it is understood by those of ordinary skill in the art that certain modifications and changes can be made to the described embodiments without departing from the spirit and scope of the present invention, as defined in the following claims.

What is claimed is:

1. A barrier stack, comprising:
a decoupling layer comprising a siloxane containing resin composition, the siloxane containing resin composition comprising a moiety derived from a siloxane monomer represented by Formula 1: 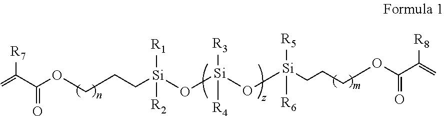
wherein:
n and m are each independently 1 to 10, and z is 0 to 5; and
R1 through R6 are each independently hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, a —O—SiR₉R₁₀R₁₁ group, or a combination thereof;
R9, R10 and R11 are each independently hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof; and
R7 and R8 are each independently hydrogen or a methyl group; and
a barrier layer on the decoupling layer.

2. The barrier stack of claim 1, further comprising a tie layer, wherein the decoupling layer is on the tie layer.

3. The barrier stack of claim 1, wherein R1 through R6 are each independently hydrogen, a substituted or unsubstituted C1 to C10 alkyl group, a substituted or unsubstituted C3 to C20 cycloalkyl group, a substituted or unsubstituted C1 to C10 hydroxyalkyl group, a substituted or unsubstituted C6 to C20 aryl group, a substituted or unsubstituted C2 to C20 heteroaryl group, a substituted or unsubstituted C2 to C10 alkenyl group, a substituted or unsubstituted C1 to C10 alkoxy group, a substituted or unsubstituted lactone group, a substituted or unsubstituted carboxyl group, a substituted or unsubstituted glycidyl ether group, a hydroxyl group, a —O—SiR₉R₁₀R₁₁ group, or a combination thereof.

4. The barrier stack of claim 1, wherein R1 through R6 are each independently hydrogen, a substituted or unsubstituted alkyl, a substituted or unsubstituted cycloalkyl, a substituted or unsubstituted aryl, —O—SiR₉R₁₀R₁₁ group, or a combination thereof.

5. The barrier stack of claim 1, wherein R1 through R6 are each independently methyl, phenyl, a —O—SiR₉R₁₀R₁₁ group, or a combination thereof.

6. The barrier stack of claim 1, wherein n and m are each independently 1 to 6, and z is 0 to 3.

7. The barrier stack of claim 1, wherein the siloxane monomer represented by Formula 1 comprises 1,5-bis(acryloxypropyl)-1,1-5,5-tetramethyl-3,3-diphenyl trisiloxane represented by Formula 2a, 1,5-bis(methacryloxypropyl)-1,1-5,5-tetramethyl-3,3-diphenyl trisiloxane represented by Formula 2b, 1,5-bis(acryloxypropyl)-1,1,3,5,5-pentamethyl-3-phenyl trisiloxane represented by Formula 3a, 1,5-bis(methacryloxypropyl)-1,1,3,5,5-pentamethyl-3-phenyl trisiloxane represented by Formula 3b, 1,9-bis(acryloxypropyl)-1,1,3,3,5,5,7,7,9,9-decamethyl hexasiloxane represented by Formula 4a, 1,9-bis(methacryloxypropyl)-1,1,3,3,5,5,7,7,9,9-decamethyl hexasiloxane represented by Formula 4b, 1,3-bis(3-acryloxypropyl)tetrakis(trimethylsiloxy)disiloxane represented by Formula 5a, 1,3-bis(3-methacryloxypropyl)tetrakis(trimethylsiloxy)disiloxane represented by Formula 5b, 1,5-bis(acryloxypropyl)-1,1,3,3,5,5-hexamethyl trisiloxane represented by Formula 6a, 1,5-bis(methacryloxypropyl)-1,1,3,3,5,5-dexamethyl trisiloxane represented by Formula 6b:

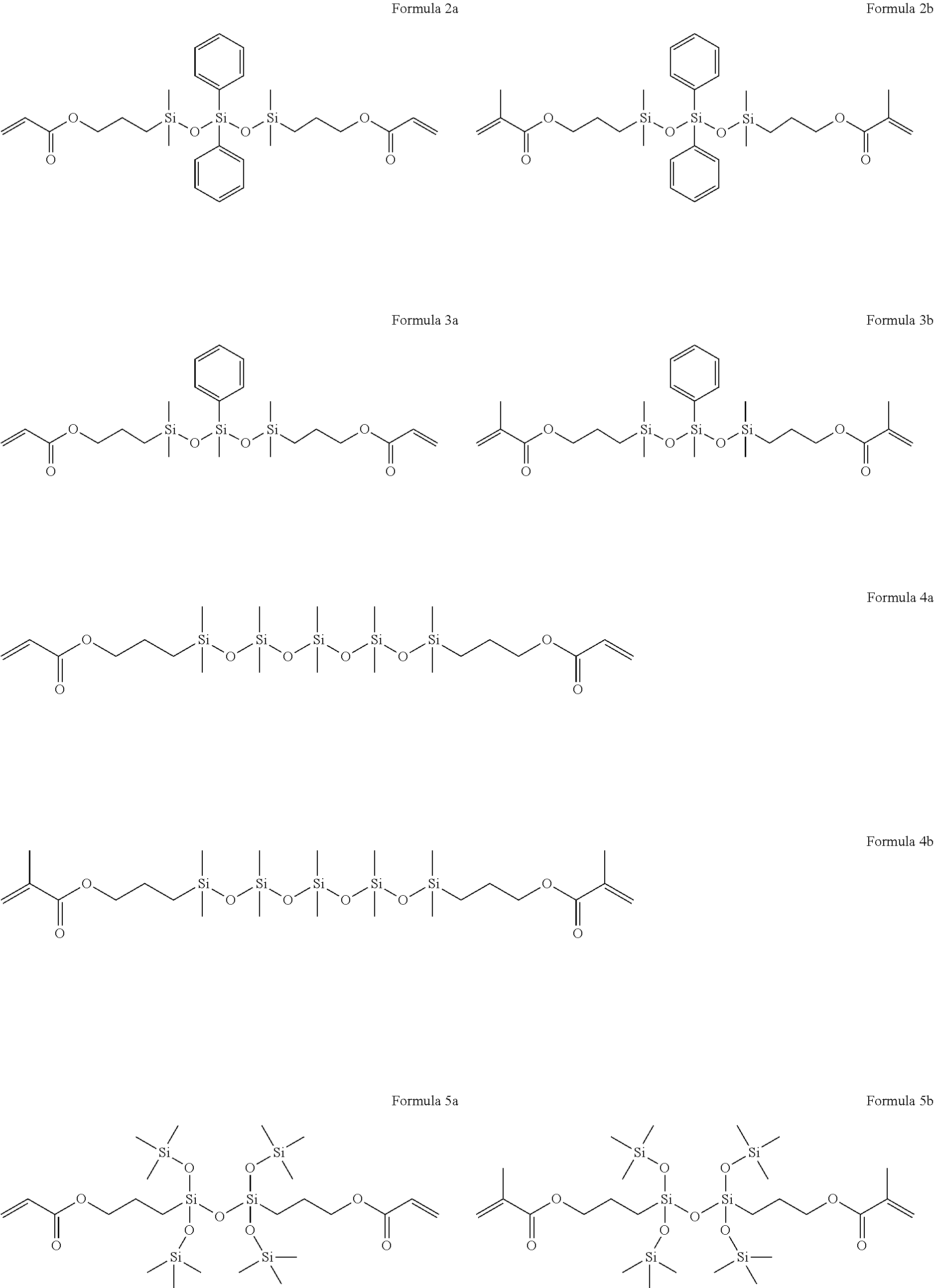

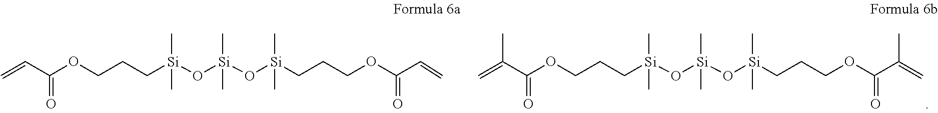

8. The barrier stack of claim 1, wherein the siloxane containing resin composition comprises a moiety derived from an acrylate or methacrylate monomer.

9. The barrier stack of claim 8, wherein the acrylate or methacrylate monomer comprises a monofunctional acrylate, a monofunctional methacrylate, a difunctional acrylate, a difunctional methacrylate, a trifunctional acrylate, and/or a trifunctional methacrylate.

10. The barrier stack of claim 8, wherein the acrylate or methacrylate monomer comprises lauryl acrylate, dodecyl dimethacrylate, and/or trimethylolpropane triacrylate.

11. A method of making a barrier stack, comprising:
forming a decoupling layer comprising a siloxane containing resin composition over a substrate by depositing a curable resin composition comprising a siloxane monomer on the substrate, and curing the curable resin composition, the siloxane monomer comprising a compound represented by Formula 1: 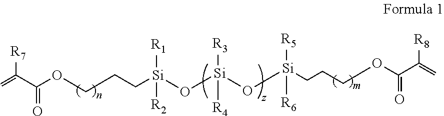
wherein:
n and m are each independently 1 to 10, and z is 0 to 5; and
R1 through R6 are each independently hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, a —O—SiR₉R₁₀R₁₁ group, or a combination thereof;
R9, R10 and R11 are each independently hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof; and
R7 and R8 are each independently hydrogen or a methyl group; and forming a barrier layer comprising an inorganic material over the decoupling layer.

12. The method of claim 11, further comprising forming a tie layer between the substrate and the decoupling layer.

13. The method of claim 11, wherein the depositing the curable resin composition on the substrate comprises flash evaporation or inkjet printing.

14. The method of claim 11, wherein the curing the curable resin composition comprises thermal curing, UV radiation, or electron beam treatment.

15. The method of claim 11, wherein the curable resin composition further comprises an acrylate-based monomer or a methacrylate-based monomer.

16. The method of claim 15, wherein the acrylate-based monomer or methacrylate based monomer comprises a monofunctional acrylate, a monofunctional methacrylate, a difunctional acrylate, a difunctional methacrylate, a trifunctional acrylate, and/or a trifunctional methacrylate.

17. The method of claim 15, wherein the acrylate-based monomer or methacrylate based monomer comprises lauryl acrylate, dodecyl dimethacrylate, and/or trimethylolpropane triacrylate.

18. The method of claim 15, wherein the acrylate-based monomer or methacrylate based monomer is present in the curable resin composition in an amount of about 30 mol % to about 80 mol % based on 100 mol % of the acrylate based monomer or methacrylate based monomer and the siloxane monomer.

19. The method of claim 15, wherein the siloxane monomer is present in the curable resin composition in an amount of about 20 mol % to about 70 mol % based on 100 mol % of the acrylate based monomer or methacrylate based monomer and the siloxane monomer.
